(19) United States
(12) Patent Application Publication
(10) Pub. No.: US 2024/0397745 A1
(43) Pub. Date: Nov. 28, 2024

(54) LIGHT-EMITTING DEVICE, DISPLAY PANEL, AND METHOD FOR MANUFACTURING THE SAME

(71) Applicant: BOE TECHNOLOGY GROUP CO., LTD., Beijing (CN)

(72) Inventors: Yang LIU, Beijing (CN); Dan WANG, Beijing (CN); Lei CHEN, Beijing (CN)

(73) Assignee: BOE TECHNOLOGY GROUP CO., LTD., Beijing (CN)

(21) Appl. No.: 18/695,177

(22) PCT Filed: Aug. 29, 2023
(86) PCT No.: PCT/CN2023/115379

§ 371 Date: Mar. 25, 2024

(30) Foreign Application Priority Data
Aug. 30, 2022 (CN) 202211058033.2

(51) Int. Cl. H10K 50/19; H10K 59/12; H10K 59/122; H10K 59/35; H10K 71/16

(52) U.S. Cl. CPC H10K 50/19; H10K 59/1201; H10K 59/122; H10K 59/353; H10K 71/166

(57) ABSTRACT

A light-emitting device includes a first electrode, at least two light-emitting units and a second electrode sequentially stacked in a first direction. The at least two light-emitting units include a first light-emitting unit and a second light-emitting unit. The first light-emitting unit includes a first light-emitting layer. The second light-emitting unit includes a second light-emitting layer. A light-emitting layer of each light-emitting unit includes a first compound, a second compound, and a third compound. An absolute value of a difference between ratios of weights of first compounds in different light-emitting layers to weights of the light-emitting layers to which the first compounds belong is in a range of 0% to 3%, and/or an absolute value of a difference between ratios of weights of second compounds in different light-emitting layers to weights of the light-emitting layers to which the second compounds belong is in a range of 0% to 3%.

### CROSS-REFERENCE TO RELATED APPLICATIONS

This application is a national phase entry under 35 USC 371 of International Patent Application No. PCT/CN2023/115379, filed on Aug. 29, 2023, which claims priority to Chinese Patent Application No. 202211058033.2, filed on Aug. 30, 2022, which are incorporated herein by reference in their entirety.

### TECHNICAL FIELD

The present disclosure relates to the field of display technologies, and in particular, to a light-emitting device, a display panel and a method for manufacturing the same.

### BACKGROUND

Organic light-emitting diodes (OLEDs) have attracted attention of enterprises and universities due to self-luminescence, high brightness, high contrast, fast response speed, wide viewing angle, simple structure, flexible display, and other advantages, and have gained rapid development.

With rapid development of organic electroluminescence technology, tandem OLEDs have become an important development direction of the OLED display technology.

### SUMMARY

In an aspect, a light-emitting device is provided. The light-emitting device includes a first electrode, at least two light-emitting units and a second electrode sequentially stacked in a first direction. The at least two light-emitting units include a first light-emitting unit and a second light-emitting unit. The first light-emitting unit is located between the first electrode and the second electrode, and the first light-emitting unit includes a first light-emitting layer. The second light-emitting unit is located between the first light-emitting unit and the second electrode, and the second light-emitting unit includes a second light-emitting layer. A light-emitting layer of each light-emitting unit includes a first compound, a second compound and a third compound. The first light-emitting layer and the second light-emitting layer satisfy at least one of: an absolute value of a difference between a ratio of a weight of a first compound in the first light-emitting layer to a weight of the first light-emitting layer and a ratio of a weight of a first compound in the second light-emitting layer to a weight of the second light-emitting layer is in a range of 0% to 3%, inclusive; and an absolute value of a difference between a ratio of a weight of a second compound in the first light-emitting layer to the weight of the first light-emitting layer and a ratio of a weight of a second compound in the second light-emitting layer to the weight of the second light-emitting layer is in a range of 0% to 3%, inclusive.

In some embodiments, in the first light-emitting layer, a ratio of the weight of the first compound to a sum of weights of the first compound and the second compound is M1. In the second light-emitting layer, a ratio of the weight of the first compound to a sum of weights of the first compound and the second compound is M2. An absolute value of a difference between M1 and M2 is in a range of 0% to 2%, inclusive.

In some embodiments, in the first light-emitting layer, a ratio of the weight of the second compound to a sum of weights of the first compound and the second compound is M3. In the second light-emitting layer, a ratio of the weight of the second compound to a sum of weights of the first compound and the second compound is M4. An absolute value of a difference between M3 and M4 is in a range of 0% to 2%, inclusive.

In some embodiments, in each light-emitting layer of the light-emitting device, a ratio of a weight of the first compound to a weight of the second compound is in a range of 3:7 to 7:3, inclusive.

In some embodiments, in each light-emitting layer of the light-emitting device, a ratio of a weight of the third compound to a sum of weights of the first compound and the second compound is in a range of 1% to 14%, inclusive.

In some embodiments, the light-emitting device further includes a charge generation layer. The charge generation layer is disposed between two adjacent light-emitting units and coupled to the adjacent light-emitting units.

In some embodiments, of the light-emitting device, an absolute value of a difference between a wavelength of light emitted by the first light-emitting layer and a wavelength of light emitted by the second light-emitting layer is less than or equal to 20 nm.

In some embodiments, the at least two light-emitting units further include a third light-emitting unit. The third light-emitting unit is located between the second light-emitting unit and the second electrode and includes a third light-emitting layer. An absolute value of a difference between a ratio of the weight of the first compound in the first light-emitting layer to the weight of the first light-emitting layer and a ratio of a weight of a first compound in the third light-emitting layer to a weight of the third light-emitting layer is in a range of 0% to 3%, inclusive; and/or an absolute value of a difference between a ratio of the weight of the second compound in the first light-emitting layer to the weight of the first light-emitting layer and a ratio of a weight of a second compound in the third light-emitting layer to the weight of the third light-emitting layer is in a range of 0% to 3%, inclusive.

In some embodiments, in the first light-emitting layer, a ratio of the weight of the first compound to a sum of weights of the first compound and the second compound is M1. In the third light-emitting layer, a ratio of the weight of the first compound to a sum of weights of the first compound and the second compound is M5. An absolute value of a difference between M1 and M5 is in a range of 0% to 2%, inclusive.

In some embodiments, in the first light-emitting layer, a ratio of the weight of the second compound to a sum of weights of the first compound and the second compound is M3. In the third light-emitting layer, a ratio of the weight of the second compound to a sum of weights of the first compound and the second compound is M6. An absolute value of a difference between M3 and M6 is in a range of 0% to 2%, inclusive.

In some embodiments, in the light-emitting device, an absolute value of a difference between the ratio of the weight of the first compound in the second light-emitting layer to the weight of the second light-emitting layer and the ratio of the weight of the first compound in the third light-emitting layer to the weight of the third light-emitting layer is in a range of 0% to 3%, inclusive; and/or an absolute value of a difference between the ratio of the weight of the second compound in the second light-emitting layer to the weight of the second light-emitting layer and the ratio of the weight of the second compound in the third light-emitting layer to the weight of the third light-emitting layer is in a range of 0% to 3%, inclusive.

In another aspect, a display panel is provided. The display panel includes a pixel defining layer and a plurality of light-emitting devices. The pixel defining layer is provided with a plurality of light-emitting openings therein. The plurality of light-emitting devices cover plurality of light-emitting openings, respectively. Each light-emitting device is the light-emitting device as described in any of the above embodiments.

In some embodiments, the plurality of light-emitting devices include a light-emitting device of a first color and a light-emitting device of a second color. A wavelength of light emitted by the light-emitting device of the first color is less than a wavelength of light emitted by the light-emitting device of the second color. A ratio of a weight of a first compound to a weight of a second compound in a light-emitting layer of the light-emitting device of the first color is greater than or equal to a ratio of a weight of a first compound to a weight of a second compound in a light-emitting layer of the light-emitting device of the second color.

In some embodiments, the ratio of the weight of the first compound to the weight of the second compound in the light-emitting layer of the light-emitting device of the first color is in a range of 5:5 to 7:3, inclusive; and the ratio of the weight of the first compound to the weight of the second compound in the light-emitting layer of the light-emitting device of the second color is in a range of 3:7 to 5:5, inclusive.

In some embodiments, the plurality of light-emitting devices in the display panel include a light-emitting device of a first color and a light-emitting device of a second color. A wavelength of light emitted by the light-emitting device of the first color is less than a wavelength of light emitted by the light-emitting device of the second color. A ratio of a weight of a third compound to a sum of weights of a first compound and a second compound in a light-emitting layer of the light-emitting device of the first color is greater than or equal to a ratio of a weight of a third compound to a sum of weights of a first compound and a second compound in a light-emitting layer of the light-emitting device of the second color.

In some embodiments, the ratio of the weight of the third compound to the sum of the weights of the first compound and the second compound in the light-emitting layer of the light-emitting device of the first color is in a range of 6% to 14%, inclusive. The ratio of the weight of the third compound to the sum of the weights of the first compound and the second compound in the light-emitting layer of the light-emitting device of the second color is in a range of 1% to 6%, inclusive.

In another aspect, a method for manufacturing a display panel is provided. The method for manufacturing the display panel includes: forming a first electrode; forming a pixel defining layer on the first electrode, the pixel defining layer being provided with a plurality of light-emitting openings therein, and a light-emitting opening exposing the first electrode; forming at least two light-emitting units covering the light-emitting opening, the at least two light-emitting units including a first light-emitting unit and a second light-emitting unit sequentially stacked in a first direction, the first light-emitting unit including a first light-emitting layer, the second light-emitting unit including a second light-emitting layer, a light-emitting layer of each light-emitting unit including a first compound, a second compound and a third compound, and the first light-emitting layer and the second light-emitting layer satisfy at least one of: an absolute value of a difference between a ratio of a weight of a first compound in the first light-emitting layer to a weight of the first light-emitting layer and a ratio of a weight of a first compound in the second light-emitting layer to a weight of the second light-emitting layer being in a range of 0% to 3%, inclusive, and an absolute value of a difference between a ratio of a weight of a second compound in the first light-emitting layer to the weight of the first light-emitting layer and a ratio of a weight of a second compound in the second light-emitting layer to the weight of the second light-emitting layer being in a range of 0% to 3%, inclusive; and forming a second electrode on a side of the at least two light-emitting units away from the first electrode, the first light-emitting unit being located between the first electrode and the second electrode, and the second light-emitting unit being located between the first light-emitting unit and the second electrode.

In some embodiments, forming the at least two light-emitting units covering the light-emitting opening includes: using an open mask to form a first transport layer, the first transport layer covering the first electrode in the light-emitting opening; using a fine metal mask to form the first light-emitting layer covering the light-emitting opening, the first light-emitting layer being located on the first transport layer; using an open mask to sequentially form a second transport layer and a third transport layer that are stacked each other, the second transport layer covering the first light-emitting layer; using a fine metal mask to form the second light-emitting layer covering the light-emitting opening, the second light-emitting layer being located on the third transport layer; and using an open mask to form a fourth transport layer, the fourth transport layer covering the second light-emitting layer.

In some embodiments, using the fine metal mask to form the first light-emitting layer covering the light-emitting opening includes: evaporating the first compound at a first temperature and the second compound at a second temperature simultaneously to allow the vaporized first compound and the vaporized second compound to pass through the fine metal mask to form the first light-emitting layer covering the light-emitting opening. An absolute value of a difference between the first temperature and the second temperature is in a range of 0° C. to 10° C., inclusive.

In some embodiments, using the fine metal mask to form the first light-emitting layer covering the light-emitting opening includes: evaporating the first compound at a first temperature, the second compound at a second temperature and the third compound at a third temperature simultaneously to allow the vaporized first compound, the vaporized second compound and the vaporized third compound to pass through the fine metal mask to form the first light-emitting layer covering the light-emitting opening. An absolute value of a difference between the third temperature and the first temperature is in a range of 0° C. to 100° C., inclusive; and/or an absolute value of a difference between the third temperature and the second temperature is in a range of 0° C. to 100° C., inclusive.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a perspective view of a display panel, in accordance with some embodiments;

FIG. 2 is a sectional view of the display panel in the embodiments shown in FIG. 1 taken along a line A-A′;

FIGS. 3 to 7 are each a structural diagram of arrangement of sub-pixels in a display panel, in accordance with some embodiments;

FIG. 8 is a sectional view of a display panel, in accordance with some embodiments;

FIG. 9 is an enlarged view of an area F in FIG. 2;

FIG. 10 is an enlarged view of an area F in FIG. 2;

FIG. 11 is a structural diagram of a light-emitting device, in accordance with some embodiments;

FIGS. 12A to 12C are each a diagram showing a structural formula of a first compound, in accordance with some embodiments;

FIG. 13 is a diagram showing a structural formula of a second compound, in accordance with some embodiments;

FIGS. 14A to 14C are diagrams showing structural formulas sequentially of a first compound, a second compound and a third compound in a light-emitting layer of a light-emitting device in Scheme 1;

FIGS. 15A to 15C are diagrams showing structural formulas sequentially of a first compound, a second compound and a third compound in a light-emitting layer of a light-emitting device in Scheme 2;

FIGS. 16A to 16C are diagrams showing structural formulas sequentially of a first compound, a second compound and a third compound in a light-emitting layer of a light-emitting device in Scheme 3;

FIGS. 17A to 17C are diagrams showing structural formulas sequentially of a first compound, a second compound and a third compound in a light-emitting layer of a light-emitting device in Scheme 4;

FIGS. 18A to 18C are diagrams showing structural formulas sequentially of a first compound, a second compound and a third compound in a light-emitting layer of a light-emitting device in Scheme 5;

FIGS. 19A to 19C are diagrams showing structural formulas sequentially of a first compound, a second compound and a third compound in a light-emitting layer of a light-emitting device in Scheme 6;

FIGS. 20A to 20C are diagrams showing structural formulas sequentially of a first compound, a second compound and a third compound in a light-emitting layer of a light-emitting device in Control scheme 1;

FIGS. 21A to 21C are diagrams showing structural formulas sequentially of a first compound, a second compound and a third compound in a light-emitting layer of a light-emitting device in Control scheme 2;

FIG. 22 is a flow diagram of a method for manufacturing a display panel, in accordance with some embodiments;

FIG. 23 is a flow diagram of a method for manufacturing a display panel, in accordance with some embodiments;

FIG. 24 is a flow diagram of a method for manufacturing a display panel, in accordance with some embodiments; and

FIG. 25 is a flow diagram of a method for manufacturing a display panel, in accordance with some embodiments.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. For example, the term “connected” may be used in the description of some embodiments to indicate that two or more components are in direct physical or electrical contact with each other. As another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of areas are enlarged for clarity. Variations in shapes relative to the accompanying drawings due to, for example, manufacturing technologies and/or tolerances may be envisaged. Therefore, the exemplary embodiments should not be construed to be limited to the shapes of areas shown herein, but to include deviations in the shapes due to, for example, manufacturing. For example, an etched area shown in a rectangular shape generally has a feature of being curved. Therefore, the areas shown in the accompanying drawings are schematic in nature, and their shapes are not intended to show actual shapes of the areas in a device, and are not intended to limit the scope of the exemplary embodiments.

How to improve an overall luminous efficiency and stability of a tandem OLED is a technical problem that needs to be solved.

In light of this, some embodiments of the present disclosure provide a light-emitting device and a display panel, which will be described below.

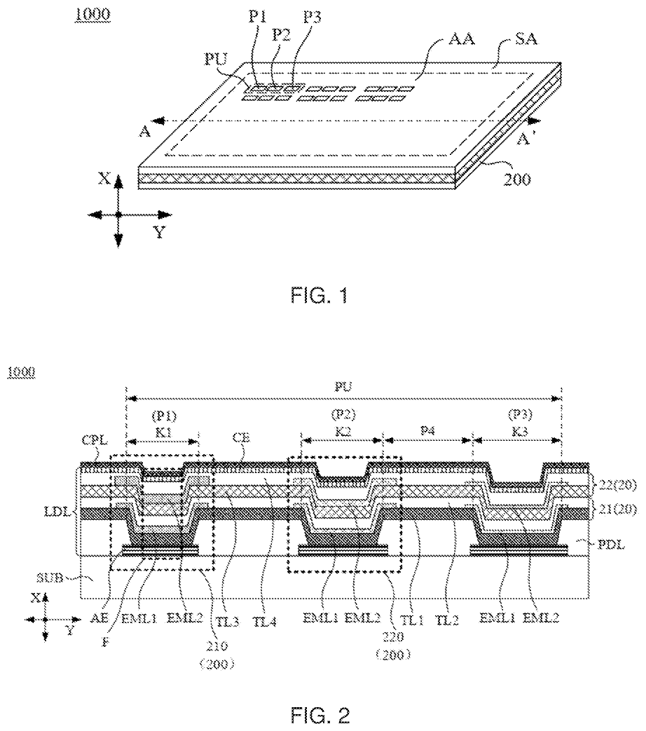

FIG. 1 is a perspective view of the display panel in accordance with some embodiments. FIG. 2 is a sectional view of the display panel in the embodiments shown in FIG. 1 taken along a line A-A′. As shown in FIG. 1, the display panel 1000 includes a display area AA for displaying images and a non-display area SA not displaying images, and the non-display area SA surrounds at least one side (e.g., one side or all sides (i.e., including an upper side, a lower side, a left side and a right side)) of the display area AA. For example, the non-display area SA may enclose the display area AA, or may be located outside the display area AA in at least one direction. A cross-sectional shape of the display panel 1000 in a plane along a second direction Y may be a rectangle, a circle, a rhombus, an ellipse, a trapezoid, or other shapes depending to display requirements, which are not limited here.

The display panel 1000 may be applied to a display apparatus. For example, the display apparatus may be a small and medium sized electronic apparatus such as a tablet computer, a smart phone, a head-mounted display, an automobile navigation unit, a camera, a central information display (CID) provided in a vehicle, a wristwatch-type electronic apparatus or any other wearable device, a personal digital assistant (PDA), a portable multimedia player (PMP) and a game console, and a medium and large sized electronic apparatus such as a television, an external billboard, a monitor, a home appliance including a display screen, a personal computer and a laptop computer. The electronic apparatuses mentioned above may represent simple examples for being applied to a display apparatus. Moreover, it may be recognized by a person of ordinary skill in the art that the display apparatus may be any other electronic apparatus without departing from the spirit and scope of the present disclosure.

In combination with FIGS. 1, 2 and 8, some embodiments of the present disclosure provide a display panel 1000.

The display panel 1000 includes a base substrate SUB, a light-emitting device layer LDL, a light extraction layer CPL and an encapsulation layer TFE.

The base substrate SUB includes a plurality of pixel unit areas PU that are repeatedly arranged. Each pixel unit area PU may include first sub-pixel area(s) P1, second sub-pixel area(s) P2 and third sub-pixel area(s) P3 for displaying different colors. For example, the first sub-pixel area P1 is configured to display red light, the second sub-pixel area P2 is configured to display green light, and the third sub-pixel area P3 is configured to display blue light.

In addition, the pixel unit area PU may further include a non-light-emitting area P4. The non-light-emitting area P4 may be located between the first sub-pixel area P1 and the second sub-pixel area P2, between the second sub-pixel area P2 and the third sub-pixel area P3, and between the third sub-pixel area P3 and the first sub-pixel area P1.

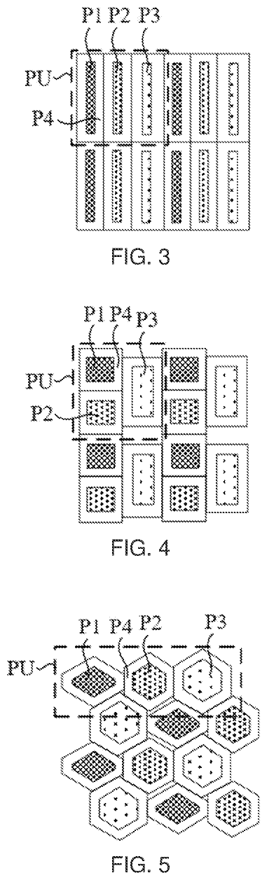

In some examples, as shown in FIGS. 3 to 5, a pixel unit area PU includes one first sub-pixel area P1, one second sub-pixel area P2 and one third sub-pixel area P3. The first sub-pixel area P1, the second sub-pixel area P2 and the third sub-pixel area P3 may be arranged spaced apart one another and arranged as a repeating unit in the display area AA.

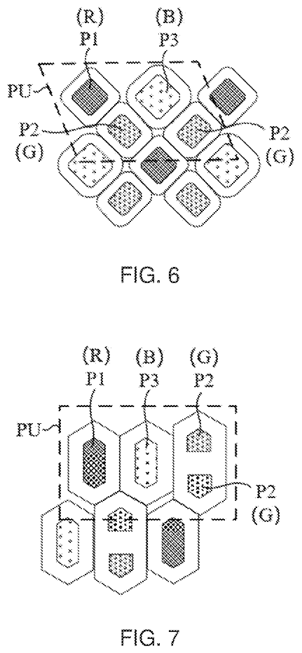

In some examples, as shown in FIGS. 6 and 7, a pixel unit area PU may include two sub-pixel areas for displaying the same color, and the two sub-pixel areas for displaying the same color may be disposed adjacently. For example, the pixel unit area PU includes one red sub-pixel area R, two green sub-pixel areas G and one blue sub-pixel area B, and the two green sub-pixel areas G in the pixel unit area PU may be disposed adjacently.

In some examples, a pixel unit area PU includes one first sub-pixel area P1, two second sub-pixel areas P2 and one third sub-pixel area P3. The first sub-pixel area P1, the two second sub-pixel areas P2 and the third sub-pixel area P3 may be arranged spaced apart one another and arranged as a repeating unit in the display area AA. In this case, the non-light-emitting area P4 may further be located between the two second sub-pixel areas P2.

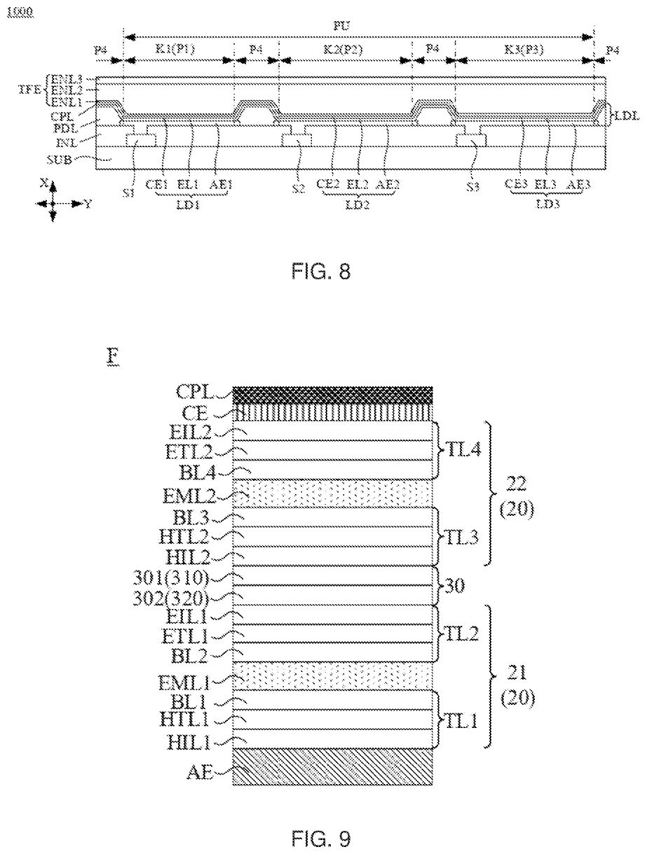

As shown in FIG. 8, the display panel 1000 may include a plurality of pixel circuits located on the base substrate SUB. A pixel unit area PU may include a first pixel circuit S1, a second pixel circuit S2 and a third pixel circuit S3. For example, the first pixel circuit S1 is located in the first sub-pixel area P1, the second pixel circuit S2 is located in the second sub-pixel area P2, and the third pixel circuit S3 is located in the third sub-pixel area P3. As another example, thin film transistors in at least one of the first pixel circuit S1, the second pixel circuit S2, and the third pixel circuit S3 may be located in the non-light-emitting area P4.

The structure of the pixel circuit varies and may be provided according to actual needs. For example, the pixel circuit may include at least two transistors and at least one capacitor. For example, the pixel circuit may have a “2T1C” structure, a “6T1C” structure, a “7T1C” structure, a “6T2C” structure, a “7T2C” structure, or the like, where “T” represents a thin film transistor, the number before “T” represents the number of thin film transistor(s), “C” represents a storage capacitor, and the number before “C” represents the number of storage capacitor(s).

Thin film transistors in at least one of the first pixel circuit S1, the second pixel circuit S2 and the third pixel circuit S3 may be thin film transistors including polysilicon or thin film transistors including oxide semiconductors. For example, in a case where the thin film transistors are the thin film transistors including oxide semiconductors, the thin film transistors each may have a top-gate thin film transistor structure. The thin film transistors may be connected to signal lines, and the signal lines include but are not limited to a gate line, a data line and a power line.

As shown in FIG. 8, the display panel 1000 may include an insulating layer INL, which may be located on the first pixel circuit S1, the second pixel circuit S2 and the third pixel circuit S3. The insulating layer INL may have a flat surface. The insulating layer INL may be made from an organic layer. For example, the insulating layer INL may include acrylic resin, epoxy resin, imide resin or ester resin. The insulating layer INL may have through holes, and the through holes are used for exposing electrodes of the first pixel circuit S1, the second pixel circuit S2 and the third pixel circuit S3, so as to achieve electrical connection.

In combination with FIGS. 2 and 8, the display panel 1000 may include the light-emitting device layer LDL and a pixel defining layer PDL that are located on the substrate SUB. The pixel defining layer PDL may be formed on the insulating layer INL, and the pixel defining layer PDL may be provided with a plurality of light-emitting openings. For example, the pixel defining layer PDL includes a first light-emitting opening K1 located in the first sub-pixel area P1, a second light-emitting opening K2 located in the second sub-pixel area P2, and a third light-emitting opening K3 located in the third sub-pixel area P3. A plurality of light-emitting devices 200 connected to the pixel circuits are formed in the light-emitting device layer LDL, and the plurality of light-emitting devices 200 respectively cover the plurality of light-emitting openings. In a pixel unit area PU, the light-emitting devices 200 include a first light-emitting device, a second light-emitting device and a third light-emitting device. For example, the first light-emitting device LD1 may cover the first light-emitting opening K1, the second light-emitting device LD2 may cover the second light-emitting opening K2, and the third light-emitting device LD3 may cover the third light-emitting opening K3. It can be understood that in FIG. 8, EL1 refers to film layer(s) located between the first electrode AE1 and the second electrode CE1 of the first light-emitting device LD1, EL2 refers to film layer(s) located between the first electrode AE2 and the second electrode CE2 of the second light-emitting device LD2, and EL3 refers to film layer(s) located between the first electrode AE3 and the second electrode CE3 of the third light-emitting device LD3.

In some embodiments, as shown in FIG. 2, the plurality of light-emitting devices 200 in the display panel 1000 include a light-emitting device 210 of a first color and a light-emitting device 220 of a second color.

For example, a wavelength of light emitted by the light-emitting device 210 of the first color is less than a wavelength of light emitted by the light-emitting device 220 of the second color.

For example, the light-emitting device 210 of the first color may be a green light-emitting device, e.g., the wavelength of the light emitted by the light-emitting device 210 of the first color may be in a range of 505 nm to 525 nm; and the light-emitting device 220 of the second color may be a red light-emitting device, e.g., the wavelength of the light emitted by the light-emitting device 220 of the second color may be in a range of 640 nm to 660 nm.

As shown in FIG. 2, the light-emitting device 200 may include a first electrode AE, at least two light-emitting units 20 and a second electrode CE that are sequentially stacked in a direction (i.e., a direction perpendicular to the base substrate SUB) X.

In some examples, the display panel 1000 is a top-emission display panel. The first electrode AE is a reflective electrode that may reflect light, such as an anode. The second electrode CE is a transmissive electrode that may transmit light, such as a cathode. In this way, a microcavity structure is formed between the anode and the cathode.

In some other examples, the display panel 1000 is a bottom-emission display panel. The first electrode AE is a transmissive electrode that may transmit light, such as an anode. The second electrode CE is a reflective electrode that may reflect light, such as a cathode. In this way, a microcavity structure is formed between the anode and the cathode.

As shown in FIG. 8, the first electrodes AE include a first electrode AE1 located in the first sub-pixel area P1, a first electrode AE2 located in the second sub-pixel area P2, and a first electrode AE3 located in the third sub-pixel area P3.

In some examples, the first electrode AE may include a material with a high work function, such as a material of a metal or a mixture of Ag, Mg, Al, Pt, Pd, Au, Ni, Nd, Ir or Cr, or may be made of a transparent conductive oxide material such as indium tin oxide (ITO), indium zinc oxide (IZO), or indium gallium zinc oxide (IGZO).

For example, the display panel 1000 is a top-emission display panel. The first electrode AE may include a laminated composite structure of transparent conductive oxide/metal/transparent conductive oxide. The material of the transparent conductive oxide is, for example, ITO or IZO, and the material of the metal is, for example, Au, Ag, Ni or Pt. For example, the anode has a structure of ITO/Ag/ITO. An average reflectivity of the first electrode AE for visible light may be in a range of 85% to 95%, inclusive.

In some examples, the display panel 1000 is a bottom-emission display panel. The first electrode AE may include a transparent conductive oxide such as ITO, IZO or IGZO.

As shown in FIG. 8, the second electrodes CE include a second electrode CE1 located in the first sub-pixel area P1, a second electrode CE2 located in the second sub-pixel area P2, and a second electrode CE3 located in the third sub-pixel area P3.

In some examples, the second electrode CE may include a metal material with a low work function or an alloy material with a low work function. The metal material is, for example, Al, Ag or Mg, and the alloy material is, for example, a Mg:Ag alloy or an Al:Li alloy.

In some embodiments, as shown in FIG. 2, at least two light-emitting units 20 between the first electrode AE and the second electrode CE may be stacked in the first direction X. The light-emitting units 20 at least include a first light-emitting unit 21 and a second light-emitting unit 22. That is, the number of the light-emitting units 20 between the first electrode AE and the second electrode CE may be two, three, or other, and is not limited here.

In some examples, as shown in FIG. 9, the at least two light-emitting units 20 include a first light-emitting unit 21 and a second light-emitting unit 22, that is, there are two light-emitting units 20 included between the first electrode AE and the second electrode CE. The first light-emitting unit 21 and the second light-emitting unit 22 are located between the first electrode AE and the second electrode CE, and the second light-emitting unit 22 is located between the first light-emitting unit 21 and the second electrode CE. For example, the first light-emitting unit 21 may be in direct contact with the first electrode AE, and the second light-emitting unit 22 may be in direct contact with the second electrode CE.

The first light-emitting unit 21 includes a first light-emitting layer EML1, a first transport layer TL1 and a second transport layer TL2. The first transport layer TL1 is located between the first light-emitting layer EML1 and the first electrode AE, and the first transport layer TL1 is configured to transport holes from the first electrode AE to the first light-emitting layer EML1. The second transport layer TL2 is located between the first light-emitting layer EML1 and the second light-emitting unit 22, and the second transport layer TL2 is configured to transport electrons to the first light-emitting layer EML1. In this way, holes and electrons may be recombined in the first light-emitting layer EML1, so that the first light-emitting layer EML1 emits light.

The second light-emitting unit 22 includes a second light-emitting layer EML2, a third transport layer TL3 and a fourth transport layer TL4. The third transport layer TL3 is located between the second light-emitting layer EML2 and the first light-emitting unit 21, and the third transport layer TL3 is configured to transport holes to the second light-emitting layer EML2. The fourth transport layer TL4 is located between the second light-emitting layer EML2 and the second electrode CE, and the fourth transport layer TL4 is configured to transport electrons from the second electrode CE to the second light-emitting layer EML2. In this way, holes and electrons may be recombined in the second light-emitting layer EML2, so that the second light-emitting layer EML2 emits light.

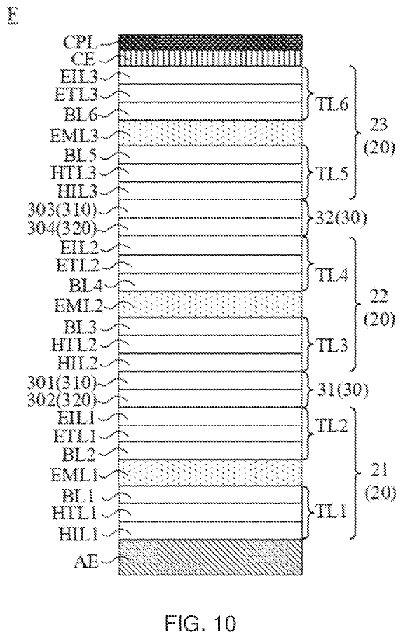

In some other examples, as shown in FIG. 10, the at least two light-emitting units 20 further include a third light-emitting unit 23, that is, there are three light-emitting units 20 included between the first electrode AE and the second electrode CE. The second light-emitting unit 22 is located between the first light-emitting unit 21 and the third light-emitting unit 23, and the third light-emitting unit 23 is located between the second light-emitting unit 22 and the second electrode CE. For example, the first light-emitting unit 21 may be in direct contact with the first electrode AE, and the third light-emitting unit 23 may be in direct contact with the second electrode CE.

The third light-emitting unit 23 includes a third light-emitting layer EML3, a fifth transport layer TL5 and a sixth transport layer TL6. The fifth transport layer TL5 is located between the third light-emitting layer EML3 and the second light-emitting unit 22, and the fifth transport layer TL5 is configured to transport holes to the third light-emitting layer EML3. The sixth transport layer TL6 is located between the third light-emitting layer EML3 and the second electrode CE, and the sixth transport layer TL6 is configured to transport electrons from the second electrode CE to the third light-emitting layer EML3. In this way, holes and electrons may be recombined in the third light-emitting layer EML3, so that the third light-emitting layer EML3 emits light.

In some embodiments, as shown in FIGS. 2 and 9, in the same light-emitting device 200, an absolute value of a difference between the wavelength of the light emitted by the first light-emitting layer EML1 and the wavelength of the light emitted by the second light-emitting layer EML2 is less than or equal to 20 nm.

A plurality of light-emitting units 20 in the same light-emitting device 200 emit the same or similar light. In this way, the concentration of the spectral superposition of the plurality of light-emitting units 20 in the same light-emitting device 200 may be improved, and color purity of the light emitted by the light-emitting device 200 and the light extraction efficiency may be improve.

For example, the light-emitting device 210 of the first color may be a green light-emitting device. In the light-emitting device 210 of the first color, the wavelength of the light emitted by the first light-emitting layer EML1 is 510 nm, the wavelength of the light emitted by the second light-emitting layer EML2 is 515 nm, and the absolute value of the difference between the two is 5 nm.

As another example, the light-emitting device 220 of the second color may be a red light-emitting device. In the light-emitting device 220 of the second color, the wavelength of the light emitted by the first light-emitting layer EML1 is 650 nm, the wavelength of the light emitted by the second light-emitting layer EML2 is 660 nm, and the absolute value of the difference between the two is 10 nm.

In some embodiments, as shown in FIGS. 9 and 10, the light-emitting device further includes charge generation layer(s) 30 each located between two adjacent light-emitting units 20, and the charge generation layer 30 is coupled to the adjacent light-emitting units 20.

For example, the charge generation layer 30 includes a P-type charge generation sub-layer 310 and an N-type charge generation sub-layer 320. For example, as shown in FIG. 9, the P-type charge generation sub-layer 310 may be in direct contact with the third transport layer TL3 to provide holes to the second light-emitting unit 22, and the N-type charge generation sub-layer 320 may be in direct contact with the second transport layer TL2 to provide electrons to the first light-emitting unit 21. As another example, as shown in FIG. 10, the P-type charge generation sub-layer 310 may be in direct contact with the fifth transport layer TL5 to provide holes to the third light-emitting unit 23, and the N-type charge generation sub-layer 320 may be in direct contact with the fourth transport layer TL4 to provide electrons to the second light-emitting unit 22.

In some examples, as shown in FIG. 10, the second transport layer TL2 is configured to transport electrons provided by a first charge generation layer 31 to the first light-emitting layer EML1, so that holes provided by the first electrode AE and the electrons provided by the first charge generation layer 31 are recombined in the first light-emitting layer EML1 to emit light. The third transport layer TL3 is configured to transport holes provided by the first charge generation layer 31 to the second light-emitting layer EML2, and the fourth transport layer TL4 is configured to transport electrons provided by a second charge generation layer 32 to the second light-emitting layer EML2, so that the holes provided by the first charge generation layer 31 and the electrons provided by the second charge generation layer 32 are recombined in the second light-emitting layer EML2 to emit light. The fifth transport layer TL5 is configured to transport holes provided by the second charge generation layer 32 to the third light-emitting layer EML3, so that the holes provided by the second charge generation layer 32 and electrons provided by the second electrode CE are recombined in the third light-emitting layer EML3 to emit light.

The charge generation layer 30 may include metal, non-doped organic substance, an organic PN junction composed of P-type and N-type dopants or metal oxide, which is not limited here.

In some examples, as shown in FIG. 9, the first transport layer TL1 may include a first hole injection layer HIL1 and a first hole transport layer HTL1. The first hole injection layer HIL1 is located between the first electrode AE and the first hole transport layer HTL1. The first hole injection layer HIL1 is configured to inject holes of the first electrode AE into the first hole transport layer HTL1. The first hole transport layer HTL1 is located between the first hole injection layer HIL1 and the first light-emitting layer EML1. The first hole transport layer HTL1 is configured to transport holes injected by the first hole injection layer HIL1 to the first light-emitting layer EML1, so as to cause the holes to be recombined with electrons in the first light-emitting layer EML1, thereby realizing the light emission of the first light-emitting layer EML1.

As shown in FIG. 9, in some examples, the first transport layer TL1 may further include a first exciton blocking layer BL1. The first exciton blocking layer BL1 may be located between the first hole transport layer HTL1 and the first light-emitting layer EML1, and the first exciton blocking layer BL1 is configured to block electrons in the first light-emitting layer EML1 from moving towards the first electrode AE. Therefore, the first exciton blocking layer BL1 may also be called an electron blocking layer (EBL).

In some examples, as shown in FIG. 9, the second transport layer TL2 may include a first electron transport layer ETL1 and a first electron injection layer EIL1. The first electron injection layer EIL1 is located between the first electron transport layer ETL1 and a first N-type charge generation sub-layer 302. The first electron injection layer EIL1 is configured to inject electrons provided by the first N-type charge generation sub-layer 302 into the first electron transport layer ETL1. The first electron transport layer ETL1 is located between the first electron injection layer EIL1 and the first light-emitting layer EML1. The first electron transport layer ETL1 is configured to transport electrons injected by the first electron injection layer EIL1 to the first light-emitting layer EML1, so as to cause the electrons to be recombined with holes in the first light-emitting layer EML1, thereby realizing the light emission of the first light-emitting layer EML1.

As shown in FIG. 9, in some examples, the second transport layer TL2 may further include a second exciton blocking layer BL2. The second exciton blocking layer BL2 may be located between the first electron transport layer ETL1 and the first light-emitting layer EML1, and the second exciton blocking layer BL2 is configured to block holes in the first light-emitting layer EML1 from moving towards the second electrode CE. Therefore, the second exciton blocking layer BL2 may also be called a hole blocking layer (HBL).

As shown in FIG. 9, in some examples, the third transport layer TL3 may include a second hole injection layer HIL2 and a second hole transport layer HTL2. The second hole injection layer HIL2 is located between a first P-type charge generation sub-layer 301 and the second hole transport layer HTL2. The second hole injection layer HIL2 is configured to inject holes of the first P-type charge generation sub-layer 301 into the second hole transport layer HTL2. The second hole transport layer HTL2 is located between the second hole injection layer HIL2 and the second light-emitting layer EML2. The second hole transport layer HTL2 is configured to transport holes injected by the second hole injection layer HIL2 to the second light-emitting layer EML2, so as to cause the holes to be recombined with electrons in the second light-emitting layer EML2, thereby realizing the light emission of the second light-emitting layer EML2.

As shown in FIG. 9, in some examples, the third transport layer TL3 may further include a third exciton blocking layer BL3. The third exciton blocking layer BL3 may be located between the second hole transport layer HTL2 and the second light-emitting layer EML2, and the third exciton blocking layer BL3 is configured to block electrons in the second light-emitting layer EML2 from moving towards the first electrode AE. Therefore, the third exciton blocking layer BL3 may also be called an electron blocking layer.

As shown in FIG. 9, in some examples, the fourth transport layer TL4 may include a second electron transport layer ETL2 and a second electron injection layer EIL2. The second electron injection layer EIL2 is located between the second electron transport layer ETL2 and the second electrode CE. The second electron injection layer EIL2 is configured to inject electrons provided by the second electrode CE into the second electron transport layer ETL2. The second electron transport layer ETL2 is located between the second electron injection layer EIL2 and the second light-emitting layer EML2. The second electron transport layer ETL2 is configured to transport electrons injected by the second electron injection layer EIL2 to the second light-emitting layer EML2, so as to cause the electrons to be recombined with holes in the second light-emitting layer EML2, thereby realizing the light emission of the second light-emitting layer EML2.

As shown in FIG. 9, in some examples, the fourth transport layer TL4 may further include a fourth exciton blocking layer BL4. The fourth exciton blocking layer BL4 may be located between the second electron transport layer ETL2 and the second light-emitting layer EML2, and the fourth exciton blocking layer BL4 is configured to block holes in the second light-emitting layer EML2 from moving towards the second electrode CE. Therefore, the fourth exciton blocking layer BL4 may also be called a hole blocking layer (HBL).

As shown in FIG. 10, in some examples, in the fourth transport layer TL4, the second electron injection layer EIL2 is located between the second electron transport layer ETL2 and a second N-type charge generation sub-layer 304, and the second electron injection layer EIL2 is configured to inject electrons provided by the second N-type charge generation sub-layer 304 into the second electron transport layer ETL2. The fifth transport layer TL5 may include a third hole injection layer HIL3 and a third hole transport layer HTL3. The third hole injection layer HIL3 is located between a second P-type charge generation sub-layer 303 and the third hole transport layer HTL3. The third hole injection layer HIL3 is configured to inject holes of the second P-type charge generation sub-layer 303 into the third hole transport layer HTL3. The third hole transport layer HTL3 is located between the third hole injection layer HIL3 and the third light-emitting layer EML3. The third hole transport layer HTL3 is configured to transport holes injected by the third hole injection layer HIL3 to the third light-emitting layer EML3, so as to cause the holes to be recombined with electrons in the third light-emitting layer EML3, thereby realizing the light emission of the third light-emitting layer EML3.

As shown in FIG. 10, in some examples, the fifth transport layer TL5 may further include a fifth exciton blocking layer BL5. The fifth exciton blocking layer BL5 may be located between the third hole transport layer HTL3 and the third light-emitting layer EML3, and the fifth exciton blocking layer BL5 is configured to block electrons in the third light-emitting layer EML3 from moving towards the first electrode AE. Therefore, the fifth exciton blocking layer BL5 may also be called an electron blocking layer.

As shown in FIG. 10, in some examples, the sixth transport layer TL6 may include a third electron transport layer ETL3 and a third electron injection layer EIL3. The third electron injection layer EIL3 is located between the third electron transport layer ETL3 and the second electrode CE. The third electron injection layer EIL3 is configured to inject electrons provided by the second electrode CE into the third electron transport layer ETL3. The third electron transport layer ETL3 is located between the third electron injection layer EIL3 and the third light-emitting layer EML3. The third electron transport layer ETL3 is configured to transport electrons injected by the third electron injection layer EIL3 to the third light-emitting layer EML3, so as to cause the electrons to be recombined with holes in the third light-emitting layer EML3, thereby realizing the light emission of the third light-emitting layer EML3.

As shown in FIG. 10, in some examples, the sixth transport layer TL6 may further include a sixth exciton blocking layer BL6. The sixth exciton blocking layer BL6 may be located between the third electron transport layer ETL3 and the third light-emitting layer EML3, and the sixth exciton blocking layer BL6 is configured to block holes in the third light-emitting layer EML3 from moving towards the second electrode CE. Therefore, the sixth exciton blocking layer BL6 may also be called a hole blocking layer (HBL).

In some examples, the first hole injection layer HIL1, the second hole injection layer HIL2, and the third hole injection layer HIL3 may include materials with strong hole injection capabilities such as copper phthalocyanine (CuPc) and HATCN, so as to form a single layer structure. In some other examples, at least one of the first hole injection layer HIL1, the second hole injection layer HIL2, and the third hole injection layer HIL3 may include a P-type doped hole injection material, and the P-type doped material is, for example, NPB:F4TCNQ, TAPC:MnO₃, or the like.

In some examples, the first hole transport layer HTL1, the second hole transport layer HTL2, and the third hole transport layer HTL3 may include carbazole-based materials with high hole mobilities, or other materials with high hole mobilities.

In some examples, the first electron injection layer EIL1, the second electron injection layer EIL2 and the third electron injection layer EIL3 may include Alq₃, alkali metal and oxides and halides thereof such as LiO₂, CaO, CsO, CsF₂, or other materials with strong electron injection capabilities.

In some examples, the first electron transport layer ETL1, the second electron transport layer ETL2, and the third electron transport layer ETL3 may include triazine-based materials with high electron mobilities, or other materials with high electron mobilities.

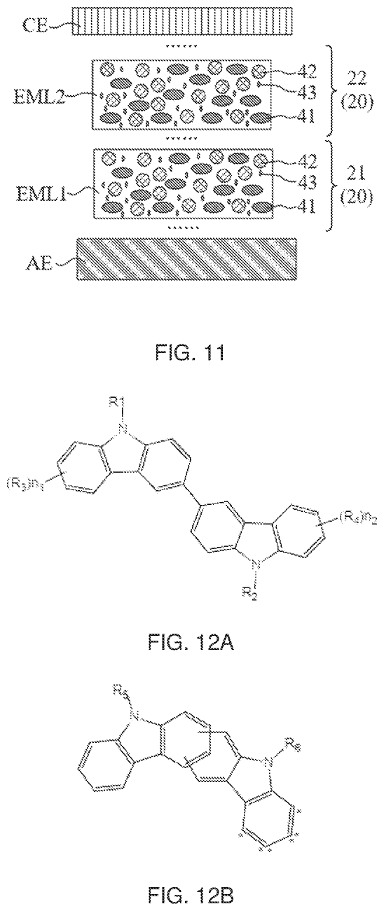

In some embodiments, as shown in FIG. 11, each light-emitting layer (e.g., EML1 and EML2) of the light-emitting units 20 of the light-emitting device 200 includes a first compound 41, a second compound 42, and a third compound 43.

The first compound 41 and the second compound 42 may be host materials of the light-emitting layer, and the third compound 43 may be a guest material (i.e., doped material) of the light-emitting layer.

In some examples, the first compound 41 may be a hole injection and transport material with good hole transport performance. For example, the first compound 41 may include, but is not limited to, aromatic amines organic materials or carbazole organic materials and derivatives thereof. For example, the first compound 41 may include three structures as shown in FIGS. 12A to 12C. In the figures, R₁ to R₆ may each be selected from any of benzene, biphenyl, naphthalene, pyridine, dibenzofuran, dibenzothiophene or carbazole; R₇ to R₉ may each be selected from any of benzene, carbazole, benzocarbazole, dibenzofuran, benzodibenzofuran, dibenzothiophene or benzodibenzothiophene; L₁, L₂ and L₃ may each be any of benzene, biphenyl or naphthalene; n₁ and n₂ are each an integer in a range of 0 to 4 such as 1, 2, 3 or 4; and n₃, n₄ and n₅ take values of 0 or 1. The * shown in FIG. 12B represents an endpoint of a carbon-carbon bond on a benzene ring, and two hydrogen atoms connected to two carbon atoms of the carbon-carbon bond may be replaced by any of benzene, naphthalene, cyclopentane or cyclohexane.

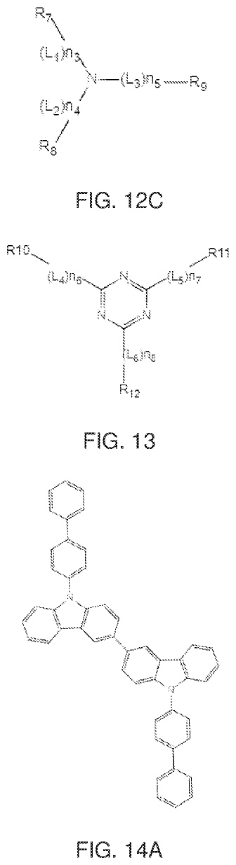

In some examples, the second compound 42 may be an electron injection and transport material with good electron transport performance. For example, the second compound 42 may include, but is not limited to, triazine-based organic materials. For example, the second compound 42 may include a structure shown in FIG. 13. In the figure, L₄ to L₆ may each be any of benzene, biphenyl, naphthalene, dibenzofuran or dibenzothiophene; n₆ to n₈ take values of 0 or 1; and R₁₀ to R₁₂ may each be any of benzene, biphenyl, naphthalene, phenanthrene, triphenylene, carbazole, benzocarbazole, dibenzofuran, benzodibenzofuran, dibenzothiophene, benzodibenzothiophene, benzoxazole, naphthoxazole or phenanthrooxazole.

In some examples, the third compound 43 may be a phosphorescent material or a fluorescent material, and has good light emission performance. For example, the phosphorescent material may include, but is not limited to, iridium complex and platinum complex, and the fluorescent material may include, but is not limited to, an organic material with thermally activated delayed fluorescence (TADF) performance. For example, the third compound 43 is an iridium complex and satisfies a general formula of Ir(L)2(L′), where L may be selected from any of phenylpyridine ligand, phenylquinoline ligand or phenylisoquinoline ligand, L′ may be selected from any of acetylacetone ligand, azadibenzofurylpyridine ligand or azadibenzothienylpyridine ligand. L and L′ may also include substituents, and the substituent may be an alkyl group containing one to six carbon atoms or a cycloalkyl group containing one to six carbon atoms.

For example, the third compound 43 in the light-emitting layer of the green light-emitting device may be a phosphorescent material, such as an iridium complex with the chemical general formula of Ir(L)2(L′), where L is a phenylpyridine ligand, and L′ is an acetylacetone ligand.

For example, the third compound 43 in the light-emitting layer of the red light-emitting device may be a phosphorescent material, such as an iridium complex with the chemical general formula of Ir(L)2(L′), where L is a phenylquinoline ligand, and L′ is an azadibenzofurylpyridine ligand.

In some examples, a sum of the number of nitrogen atoms N in the first compound 41, the number of nitrogen atoms N in the second compound 42, and the number of nitrogen atoms N in the third compound 43 is in a range of 7 to 12, inclusive, such as 7, 8, 9, 10, 11 or 12. As another example, the number of nitrogen atoms N in the first compound 41 is 2, the number of nitrogen atoms N in the second compound 42 is 3, the number of nitrogen atoms N in the third compound 43 is 2, and the sum of the numbers of nitrogen atoms N in the first compound 41, the second compound 42 and the third compound 43 is 7.

In some embodiments, a light-emitting device includes a plurality of light-emitting layers, and an absolute value of a difference between ratios of weights of first compounds in different light-emitting layers to weights of the light-emitting layers to which the first compounds belong is in a range of 0% to 3%, inclusive. It can be understood that, as shown in FIG. 11, in the light-emitting device, an absolute value of a difference between a ratio of a weight of the first compound 41 in the first light-emitting layer EML1 to a weight of the first light-emitting layer EML1 and a ratio of a weight of the first compound 41 in the second light-emitting layer EML2 to a weight of the second light-emitting layer EML2 is in the range of 0% to 3%, inclusive, such as 0%, 0.2%, 0.3%, 0.5%, 0.8%, 1%, 1.2%, 1.5%, 1.7%, 2%, 2.3%, 2.5%, 2.9% or 3%.

In the same tandem OLED, ratios of weights of first compounds in different light-emitting layers to weights of the light-emitting layers to which the first compounds belong have a relatively great difference, and/or ratios of weights of second compounds in different light-emitting layers to weights of the light-emitting layers to which the second compounds belong have a relatively great difference. As a result, hole transport performance and/or electron transport performance of different light-emitting layers in the same tandem OLED have a great difference, and exciton recombination areas of different light-emitting layers are inconsistent, resulting in low overall luminous efficiency and poor stability of the tandem OLED.

The difference between the ratios of the weights of the first compounds 41 in different light-emitting layers in the same light-emitting device to the weights of the light-emitting layers to which the first compounds 41 belong is defined. It can be understood that the difference in weight ratio between the first compounds 41 of different light-emitting layers in the light-emitting device is reduced, so that the hole injection and hole transport performances of different light-emitting layers in the light-emitting device are similar, and thus the exciton recombination areas of different light-emitting layers in the same light-emitting device are substantially consistent or close, thereby improving overall luminous efficiency and stability of the light-emitting device and the display panel. For example, as shown in FIG. 11, in the light-emitting device, a ratio of the weight of the first compound 41 in the first light-emitting layer EML1 to a sum of the weights of the first compound 41 and the second compound 42 in the first light-emitting layer EML1 is M1; and a ratio of the weight of the first compound 41 in the second light-emitting layer EML2 to a sum of the weights of the first compound 41 and the second compound 42 in the second light-emitting layer EML2 is M2. An absolute value of a difference between M1 and M2 is in a range of 0% to 2%, inclusive, such as 0%, 0.1%, 0.3%, 0.6%, 0.8%, 1%, 1.2%, 1.5%, 1.7% or 2%.

For example, in the first light-emitting layer EML1 and the second light-emitting layer EML2, the first compounds 41 are aromatic amines organic materials, and the second compounds 42 are triazine-based organic materials. In the first light-emitting layer EML1, a ratio of the weight of the aromatic amines organic material to a sum of the weights of the aromatic amines organic material and the triazine-based organic material is M10. In the second light-emitting layer EML2, a ratio of the weight of the aromatic amines organic material to a sum of the weights of the aromatic amines organic material and the triazine-based organic material is M20. An absolute value of a difference between M10 and M20 is less than or equal to 0.5%.

In some examples, as shown in FIG. 10, in the light-emitting device, the at least two light-emitting units 20 further include a third light-emitting unit 23. The third light-emitting unit 23 is located between the second light-emitting unit 22 and the second electrode CE, and includes a third light-emitting layer EML3. It can be understood that there are three light-emitting units 20 in a light-emitting device, and the three light-emitting units 20 respectively include a first light-emitting layer EML1, a second light-emitting layer EML2, and a third light-emitting layer EML3.

For example, in a light-emitting device, an absolute value of a difference between a ratio of the weight of the first compound 41 in the first light-emitting layer EML1 to the weight of the first light-emitting layer EML1 and a ratio of the weight of the first compound 41 in the third light-emitting layer EML3 to the weight of the third light-emitting layer EML3 is in a range of 0% to 3%, inclusive, such as 0%, 0.2%, 0.3%, 0.5%, 0.8%, 1%, 1.2%, 1.5%, 1.7%, 2%, 2.3%, 2.5%, 2.9% or 3%.

For example, in the light-emitting device, a ratio of the weight of the first compound 41 in the first light-emitting layer EML1 to a sum of the weights of the first compound 41 and the second compound 42 in the first light-emitting layer EML1 is M1; and a ratio of the weight of the first compound 41 in the third light-emitting layer EML3 to a sum of the weights of the first compound 41 and the second compound 42 in the third light-emitting layer EML3 is M5. An absolute value of a difference between M1 and M5 is in a range of 0% to 2%, inclusive, such as 0%, 0.1%, 0.3%, 0.5%, 0.6%, 0.8%, 1%, 1.2%, 1.5%, 1.7% or 2%.

For example, an absolute value of a difference between a ratio of the weight of the first compound 41 in the second light-emitting layer EML2 to the weight of the second light-emitting layer EML2 and a ratio of the weight of the first compound 41 in the third light-emitting layer EML3 to the weight of the third light-emitting layer EML3 is in a range of 0% to 3%, inclusive.

For example, in the light-emitting device, a ratio of the weight of the first compound 41 in the second light-emitting layer EML2 to a sum of the weights of the first compound 41 and the second compound 42 in the second light-emitting layer EML2 is M2; and a ratio of the weight of the first compound 41 in the third light-emitting layer EML3 to a sum of the weights of the first compound 41 and the second compound 42 in the third light-emitting layer EML3 is M5. An absolute value of a difference between M2 and M5 is in a range of 0% to 2%, inclusive, such as 0%, 0.1%, 0.3%, 0.5%, 0.6%, 0.8%, 1%, 1.2%, 1.5%, 1.7% or 2%.

In this way, a difference between ratios of weights of first compounds 41 in different light-emitting layers in the light-emitting device to weights of the light-emitting layers to which the first compounds 41 belong may be reduced, that is, a difference between ratios of weights of hole injection and transport materials in different light-emitting layers in the same light-emitting device to weights of the light-emitting layers to which the hole injection and transport materials belong may be reduced. Therefore, a difference between hole transport performances of different light-emitting layers in the same light-emitting device may be reduced, thereby improving the overall luminous efficiency and stability of the light-emitting device.

In some embodiments, as shown in FIGS. 9, 10 and 11, a light-emitting device includes a plurality of light-emitting layers, and an absolute value of a difference between ratios of weights of second compounds 42 in different light-emitting layers to weights of the light-emitting layers to which the second compounds 42 belong is in a range of 0% to 3%, inclusive. It can be understood that in the light-emitting device, an absolute value of a difference between a ratio of a weight of the second compound 42 in the first light-emitting layer EML1 to a weight of the first light-emitting layer EML1 and a ratio of a weight of the second compound 42 in the second light-emitting layer EML2 to a weight of the second light-emitting layer EML2 is in the range of 0% to 3%, inclusive, such as 0%, 0.2%, 0.3%, 0.5%, 0.8%, 1%, 1.2%, 1.5%, 1.7%, 2%, 2.3%, 2.5%, 2.9% or 3%.

The difference between the ratios of the weights of the second compounds 42 in different light-emitting layers in the same light-emitting device to the weights of the light-emitting layers to which the second compounds 42 belong is defined. It can be understood that the difference in weight ratio between the second compounds 42 of different light-emitting layers in the same light-emitting device is reduced, so that the electron injection and transport performances of different light-emitting layers in the light-emitting device are similar, and thus the exciton recombination areas of different light-emitting layers in the same light-emitting device are substantially consistent or close, thereby improving overall luminous efficiency and stability of the light-emitting device and the display panel 1000.

For example, a ratio of the weight of the second compound 42 in the first light-emitting layer EML1 to a sum of the weights of the first compound 41 and the second compound 42 in the first light-emitting layer EML1 is M3; and a ratio of the weight of the second compound 42 in the second light-emitting layer EML2 to a sum of the weights of the first compound 41 and the second compound 42 in the second light-emitting layer EML2 is M4. An absolute value of a difference between M3 and M4 is in a range of 0% to 2%, inclusive, such as 0%, 0.1%, 0.3%, 0.6%, 0.8%, 1%, 1.2%, 1.5%, 1.7% or 2%.

For example, in the first light-emitting layer EML1 and the second light-emitting layer EML2, the first compounds 41 are aromatic amines organic materials, and the second compounds 42 are triazine-based organic materials. In the first light-emitting layer EML1, a ratio of the weight of the triazine-based organic material to a sum of the weights of the aromatic amines organic material and the triazine-based organic material is M30. In the second light-emitting layer EML2, a ratio of the weight of the triazine-based organic material to a sum of the weights of the aromatic amines organic material and the triazine-based organic material is M40. An absolute value of a difference between M30 and M40 is 0.5%.

For example, an absolute value of a difference between a ratio of the weight of the second compound 42 in the first light-emitting layer EML1 to the weight of the first light-emitting layer EML1 and a ratio of the weight of the second compound 42 in the third light-emitting layer to the weight of the third light-emitting layer is in a range of 0% to 3%, inclusive, such as 0%, 0.2%, 0.3%, 0.5%, 0.8%, 1%, 1.2%, 1.5%, 1.7%, 2%, 2.3%, 2.5%, 2.9% or 3%.

For example, in the light-emitting device, a ratio of the weight of the second compound 42 in the first light-emitting layer EML1 to a sum of the weights of the first compound 41 and the second compound 42 in the first light-emitting layer EML1 is M3; and a ratio of the weight of the second compound 42 in the third light-emitting layer EML3 to a sum of the weights of the first compound 41 and the second compound 42 in the third light-emitting layer EML3 is M6. An absolute value of a difference between M3 and M6 is in a range of 0% to 2%, inclusive, such as 0%, 0.1%, 0.3%, 0.5%, 0.6%, 0.8%, 1%, 1.2%, 1.5%, 1.7% or 2%.

For example, an absolute value of a difference between a ratio of the weight of the second compound 42 in the second light-emitting layer EML2 to the weight of the second light-emitting layer EML2 and a ratio of the weight of the second compound 42 in the third light-emitting layer to the weight of the third light-emitting layer is in a range of 0% to 3%, inclusive, such as 0%, 0.2%, 0.3%, 0.5%, 0.8%, 1%, 1.2%, 1.5%, 1.7%, 2%, 2.3%, 2.5%, 2.9% or 3%.

For example, in the light-emitting device, a ratio of the weight of the second compound 42 in the second light-emitting layer EML2 to a sum of the weights of the first compound 41 and the second compound 42 in the second light-emitting layer EML2 is M4; and a ratio of the weight of the second compound 42 in the third light-emitting layer EML3 to a sum of the weights of the first compound 41 and the second compound 42 in the third light-emitting layer EML3 is M6. An absolute value of a difference between M4 and M6 is in a range of 0% to 2%, inclusive, such as 0%, 0.1%, 0.3%, 0.5%, 0.6%, 0.8%, 1%, 1.2%, 1.5%, 1.7% or 2%.

In this way, a difference between ratios of weights of second compounds 42 in different light-emitting layers in the light-emitting device to weights of the light-emitting layers to which the second compounds 42 belong may be reduced, that is, a difference between ratios of weights of electron injection and transport materials in different light-emitting layers in the same light-emitting device to weights of the light-emitting layers to which the electron injection and transport materials belong may be reduced. Therefore, a difference between electron transport performances of different light-emitting layers in the same light-emitting device may be reduced, thereby improving the overall luminous efficiency and stability of the light-emitting device.

In some examples, as shown in FIG. 11, in a case where the weight of the third compound 43 in the first light-emitting layer EML1 and the weight of the third compound 43 in the second light-emitting layer EML2 are the same, an absolute value of a difference between a ratio of a sum of the weights of the first compound 41 and the second compound 42 in the first light-emitting layer EML1 to the weight of the first light-emitting layer EML1 and a ratio of a sum of the weights of the first compound 41 and the second compound 42 in the second light-emitting layer EML2 to the weight of the second light-emitting layer EML2 is also in a range of 0% to 3%, inclusive.

In this way, a difference between ratios of weights of host materials in different light-emitting layers in the light-emitting device to weights of the light-emitting layers to which the host materials belong may be reduced, and a difference between hole transport performances of different light-emitting layers in the same light-emitting device and a difference between electron transport performances of different light-emitting layers in the same light-emitting device may be reduced, thereby improving the overall luminous efficiency and stability of the light-emitting device.

In some embodiments, in a light-emitting device, an absolute value of a difference between a ratio of the weight of the third compound 43 in the first light-emitting layer EML1 to the weight of first light-emitting layer EML1 and a ratio of the weight of the third compound 43 in the second light-emitting layer EML2 to the weight of the second light-emitting layer EML2 is in a range of 0% to 3%, inclusive, such as 0%, 0.2%, 0.3%, 0.5%, 0.8%, 1%, 1.2%, 1.5%, 1.7%, 2%, 2.3%, 2.5%, 2.9% or 3%.

In this way, a difference between ratios of weights of guest materials in different light-emitting layers in the light-emitting device to weights of the light-emitting layers to which the guest materials belong may be reduced, and a difference between luminous efficiencies of different light-emitting layers in the same light-emitting device may be reduced, thereby improving the overall luminous efficiency and stability of the light-emitting device.

In some embodiments, in each light-emitting layer of the light-emitting device, a ratio of the weight of the first compound 41 to the weight of the second compound 42 is in a range of 3:7 to 7:3, inclusive, such as 3:7, 4:7, 5:6, 6:7, 7:8, 7:7, 7:6, 7:5, 7:4 or 7:3.

The range of the ratio of the weight of the first compound 41 to the weight of the second compound 42 in each light-emitting layer can be understood as the range of the ratio of the weights of the two host materials in the light-emitting layer. By adjusting the ratio of the weights of the two host materials as needed, the hole transport efficiency or electron transport efficiency of the light-emitting layer may be adjusted, thereby adjusting the luminous efficiency of the light-emitting layer.

In some embodiments, as shown in FIGS. 2 and 11, a ratio of a weight of a first compound 41 to a weight of a second compound 42 in a light-emitting layer of the light-emitting device 210 of the first color is greater than or equal to a ratio of a weight of a first compound 41 to a weight of a second compound 42 in a light-emitting layer of the light-emitting device 220 of the second color.

For example, a ratio of a weight of a first compound 41 to a weight of a second compound 42 in each light-emitting layer of the light-emitting device 210 of the first color is greater than or equal to a ratio of a weight of a first compound 41 to a weight of a second compound 42 in each light-emitting layer of the light-emitting device 220 of the second color. As another example, a ratio of a sum of weights of first compounds 41 to a sum of weights of second compounds 42 in all light-emitting layers of the light-emitting device 210 of the first color is greater than or equal to a ratio of a sum of weights of first compounds 41 to a sum of weights of second compounds 42 in all light-emitting layers of the light-emitting device 220 of the second color.

In some examples, in the light-emitting layer of the light-emitting device 210 of the first color, a ratio of the weight of the first compound 41 to the weight of the second compound 42 is in a range of 5:5 to 7:3, inclusive, such as 5:5, 7:6, 5:4, 6:5, 7:5, 7:4 or 7:3. In the light-emitting layer of the light-emitting device 220 of the second color, a ratio of the weight of the first compound 41 to the weight of the second compound 42 is in a range of 3:7 to 5:5, inclusive, such as 3:7, 4:7, 5:6, 6:7, 7:8 or 5:5.

For example, the light-emitting device 210 of the first color is a green light-emitting device. In the light-emitting layer of the light-emitting device 210 of the first color, a ratio of the weight of the first compound 41 to the weight of the second compound 42 may be 7:3. The light-emitting device 220 of the second color is a red light-emitting device. In the light-emitting layer of the light-emitting device 220 of the second color, a ratio of the weight of the first compound 41 to the weight of the second compound 42 may be 3:7.

In this way, by adjusting the ratio of the weights of the two host materials in the light-emitting layer, the luminous efficiencies of the light-emitting layers of different colors may be adjusted, thereby improving the color balance performance of the display panel.

In some embodiments, in each light-emitting layer of the light-emitting device, a ratio of the weight of the third compound 43 to a sum of the weights of the first compound 41 and the second compound 42 is in a range of 1% to 14%, inclusive, such as 1%, 2%, 3%, 5%, 6%, 8%, 10%, 12% or 14%.

In each light-emitting layer, the ratio of the weight of the third compound 43 to the sum of the weights of the first compound 41 and the second compound 42 may be understood as the ratio of the weight of the guest material in the light-emitting layer to the sum of the weights of the two host materials in the light-emitting layer. Since the guest material has a high luminous efficiency, by doping the host materials of the light-emitting layer with a certain ratio of guest material, the luminous efficiency may be improved and the color of the electroluminescence of the light-emitting layer may be changed.

In some examples, as shown in FIGS. 2 and 11, a ratio of the weight of the third compound 43 in the light-emitting layer of the light-emitting device 210 of the first color and the sum of the weights of the first compound 41 and the second compound 42 in the light-emitting layer of the light-emitting device 210 of the first color is greater than or equal to a ratio of the weight of the third compound 43 in the light-emitting layer of the light-emitting device 220 of the second color to the sum of the weights of the first compound 41 and the second compound 42 in the light-emitting layer of the light-emitting device 220 of the second color.

For example, in the light-emitting layer of the light-emitting device 210 of the first color, the ratio of the weight of the third compound 43 to the sum of the weights of the first compound 41 and the second compound 42 is in a range of 6% to 14%, inclusive, such as 6%, 7%, 8%, 9%, 10%, 11%, 12%, 13% or 14%. Moreover, in the light-emitting layer of the light-emitting device 220 of the second color, the ratio of the weight of the third compound 43 to the sum of the weights of the first compound 41 and the second compound 42 is in a range of 1% to 6%, inclusive, such as 1%, 1.5%, 2%, 2.4%, 3%, 3.5%, 4%, 4.5%, 5%, 5.6% or 6%.

For example, the light-emitting device 210 of the first color is a green light-emitting device. In the light-emitting layer of the light-emitting device 210 of the first color, the ratio of the weight of the third compound 43 to the sum of the weights of the first compound 41 and the second compound 42 may be 14%. Moreover, the light-emitting device 220 of the second color is a red light-emitting device. In the light-emitting layer of the light-emitting device 220 of the second color, the ratio of the weight of the third compound 43 to the sum of the weights of the first compound 41 and the second compound 42 may be 2%.

In the present embodiments, the ratio of the weight of the guest material (i.e., the third compound 43) in the light-emitting layer to the sum of the weights of the two host materials (i.e., the first compound 41 and the second compound 42) in the light-emitting layer is further defined. Thus, of different light-emitting layers in the light-emitting device of the same color, the difference between ratios of weights of guest materials to sums of weights of two host materials may be reduced, and the overall luminous efficiency and stability of the light-emitting device 200 may be improved.

As shown in FIG. 2, the display panel 1000 is a top-emission display panel, and the light extraction layer CPL covers the light-emitting device layer LDL. For example, the light extraction layer CPL is directly located on the second electrode CE. The light extraction layer CPL may improve the light extraction efficiency of the light-emitting device layer LDL. The light extraction layer CPL has a large refractive index and a small light absorption coefficient.

As shown in FIG. 8, the encapsulation layer TFE is used to encapsulate the light-emitting device layer LDL and the light extraction layer CPL. In some embodiments, the encapsulation layer TFE may include a first encapsulation layer ENL1, a second encapsulation layer ENL2 and a third encapsulation layer ENL3 that are stacked. For example, the first encapsulation layer ENL1 and the third encapsulation layer ENL3 are each made of inorganic material(s), and the inorganic material(s) are selected from at least one of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON) or lithium fluoride. As another example, the second encapsulation layer ENL2 is made of organic material(s), and the organic material(s) are selected from at least one of acrylic resin, methacrylic resin, polyisoprene, vinyl resin, epoxy resin, polyurethane resin, cellulose resin or perylene resin. The number of layers, the material and the structure of the thin film encapsulation layer TFE may be varied by those skilled in the art according to requirements, and are not limited thereto in the present disclosure.

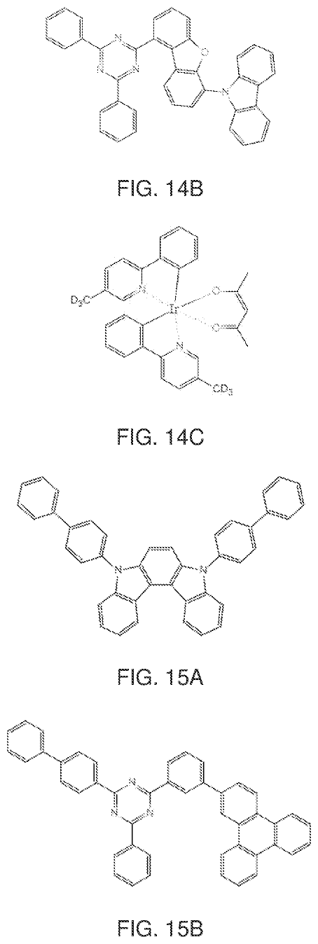

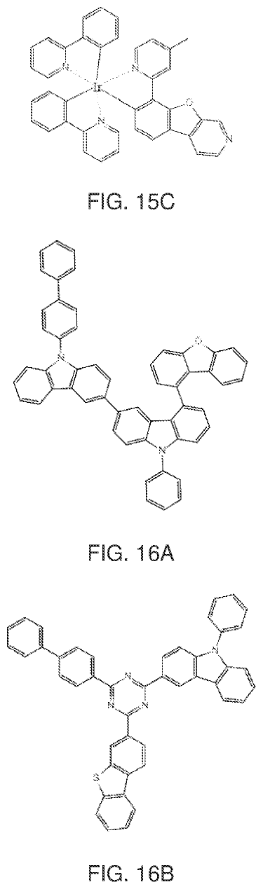

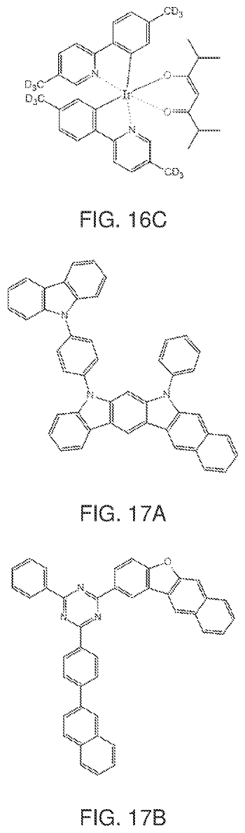

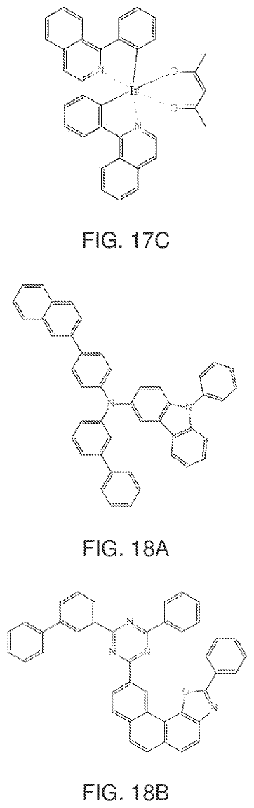

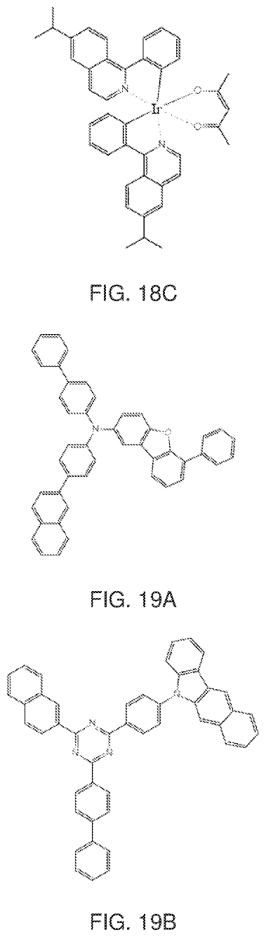

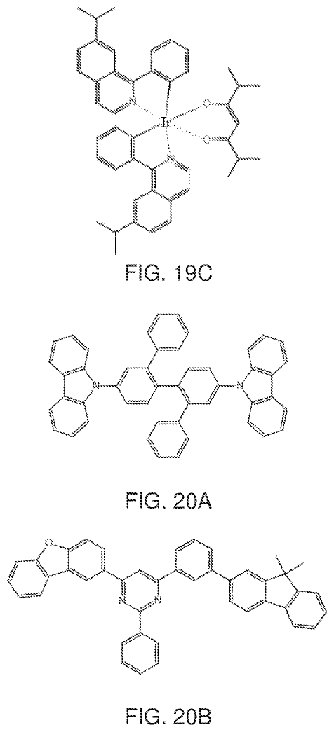

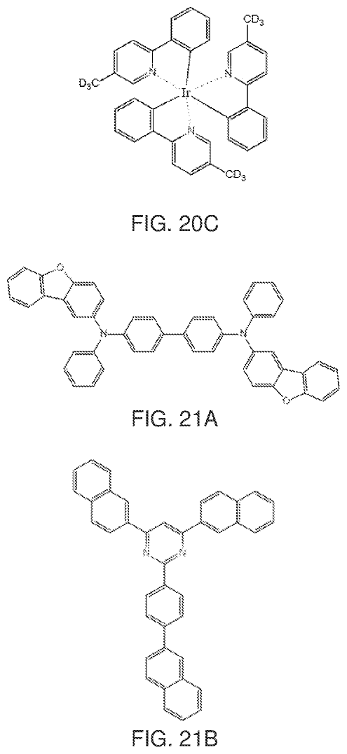

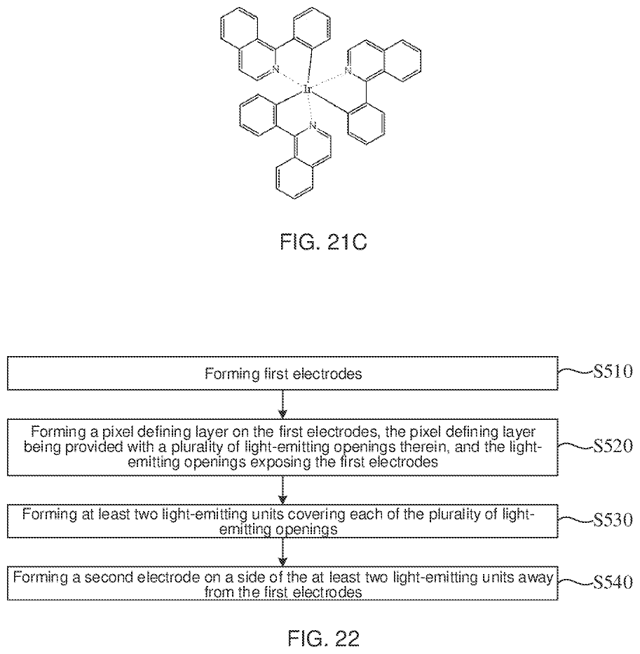

FIGS. 14A and 15A to 21A are diagrams showing structural formulas of first compounds 41 in 6 sets of schemes and 2 sets of control schemes provided by the present disclosure. FIGS. 14B and 15B to 21B are diagrams showing structural formulas of second compounds 42 in the 6 sets of schemes and 2 sets of control schemes provided by the present disclosure. FIGS. 14C and 15C to 21C are diagrams showing structural formulas of third compounds 43 in the 6 sets of schemes and 2 sets of control schemes provided by the present disclosure.

Referring to FIGS. 14A to 21C, the embodiments of the present disclosure provides 6 sets of schemes and 2 sets of control schemes for comparison. The parameters of the 6 sets of schemes and 2 sets of control schemes are seen for detailed in Table 1.

TABLE 1

| | | Weight | Weight | Weight | | | |
|---|---|---|---|---|---|---|---|
| | | ratio of | ratio of | ratio of | First | Second | Third |
| | | first | second | third | temperature | temperature | temperature |
| Name | | compound | compound | compound | T1/° C. | T2/° C. | T3/° C. |
| Scheme | First | 60.4% | 39.6% | 12.0% | 154.3 | 154.8 | 221.5 |
| 1 | light-emitting | | | | | | |
| | layer | | | | | | |
| | Second | 60.3% | 39.7% | 11.9% | | | |
| | light-emitting | | | | | | |
| | layer | | | | | | |
| Scheme | First | 69.2% | 30.8% | 14.0% | 148.1 | 148.7 | 231.1 |
| 2 | light-emitting | | | | | | |
| | layer | | | | | | |
| | Second | 69.0% | 31.0% | 13.9% | | | |
| | light-emitting | | | | | | |
| | layer | | | | | | |
| Scheme | First | 40.4% | 59.6% | 2.1% | 178.1 | 179.1 | 206.7 |
| 3 | light-emitting | | | | | | |
| | layer | | | | | | |
| | Second | 40.0% | 60.0% | 2.0% | | | |
| | light-emitting | | | | | | |
| | layer | | | | | | |
| Scheme | First | 30.4% | 69.6% | 1.3% | 166.8 | 165.9 | 211.4 |
| 4 | light-emitting | | | | | | |
| | layer | | | | | | |
| | Second | 30.0% | 70.0% | 1.1% | | | |
| | light-emitting | | | | | | |
| | layer | | | | | | |
| Scheme | First | 65.3% | 34.7% | 10.0% | 150.6 | 151.8 | 225.4 |
| 5 | light-emitting | | | | | | |
| | layer | | | | | | |
| | Second | 65.2% | 34.8% | 9.9% | | | |
| | light-emitting | | | | | | |
| | layer | | | | | | |
| | Third | 65.3% | 34.7% | 10.1% | | | |
| | light-emitting | | | | | | |
| | layer | | | | | | |
| Scheme | First | 35.4% | 64.6% | 3.0% | 172.2 | 174.3 | 208.6 |
| 6 | light-emitting | | | | | | |
| | layer | | | | | | |
| | Second | 35.3% | 64.7% | 2.9% | | | |
| | light-emitting | | | | | | |
| | layer | | | | | | |
| | Third | 35.4% | 64.6% | 3.0% | | | |
| | light-emitting | | | | | | |
| | layer | | | | | | |
| Control | First | 60.7% | 39.3% | 12.0% | 149.4 | 155.2 | 256.7 |
| scheme | light-emitting | | | | | | |
| 1 | layer | | | | | | |
| | Second | 59.9% | 40.1% | 11.6% | | | |
| | light-emitting | | | | | | |
| | layer | | | | | | |
| Control | First | 40.8% | 59.2% | 2.1% | 171.2 | 176.8 | 268.5 |
| scheme | light-emitting | | | | | | |
| 2 | layer | | | | | | |
| | Second | 40.1% | 59.9% | 2.0% | | | |
| | light-emitting | | | | | | |
| | layer | | | | | | |

In Table 1, the “weight ratio of first compound” indicates a ratio of the weight of the first compound in each light-emitting layer to a sum of the weights of the first compound and the second compound; the “weight ratio of second compound” indicates a ratio of the weight of the second compound in each light-emitting layer to a sum of the weights of the first compound and the second compound; and the “weight ratio of third compound” indicates a ratio of the weight of the third compound in each light-emitting layer to a sum of the weights of the first compound and the second compound.

TABLE 2

| Device | Name | V | Cd/A | CIE x | CIE y | LT95 |
|---|---|---|---|---|---|---|
| Light-emitting | Scheme 1 | 100% | 100% | 0.241 | 0.720 | 100% |
| device of first | Scheme 2 | 106% | 103% | 0.241 | 0.720 | 112% |
| color | Scheme 5 | 132% | 128% | 0.241 | 0.720 | 142% |
| | Control | 101% | 93% | 0.241 | 0.720 | 89% |
| | scheme 1 | | | | | |
| Light-emitting | Scheme 3 | 100% | 100% | 0.680 | 0.320 | 100% |
| device of second | Scheme 4 | 92% | 98% | 0.680 | 0.320 | 102% |
| color | Scheme 6 | 131% | 135% | 0.680 | 0.320 | 158% |
| | Control | 100% | 91% | 0.680 | 0.320 | 86% |
| | scheme 2 | | | | | |

In Table 2, the “V” indicates a driving voltage of the light-emitting device; the “Cd/A” indicates a current luminous efficiency; the “CIE x” indicates a value of a color coordinate x of the light-emitting device; the “CIE y” indicates a value of a color coordinate y of the light-emitting device value; the “LT95” indicates time required for the brightness of the light-emitting device to drop to 95% of the initial brightness, that is, the effective service life of the light-emitting device.

The values of the color coordinates in Scheme 1, the values of the color coordinates in Scheme 2, the values of the color coordinates in Scheme 5 and the values of the color coordinates in Control scheme 1 are the same. In Table 2, for parameters of the light-emitting device 210 of the first color, each parameter (i.e., driving voltage, current luminous efficiency and effective service life) of Scheme 1 is set to be 100% as a standard, and each parameter of Scheme 2, each parameter of Scheme 5, and each parameter of Control scheme 1 are all relative quantities of the respective parameter of Scheme 1. Similarly, the values of the color coordinates in scheme 3, the values of the color coordinates in scheme 4, the values of the color coordinates in scheme 6 and the values of the color coordinates in Control scheme 2 are the same. In Table 2, for parameters of the light-emitting device 220 of the second color, each parameter of Scheme 3 is set to be 100% as a standard, and each parameter of Scheme 4, each parameter of Scheme 5, and each parameter of Control scheme 2 are all relative quantities of the respective parameter of Scheme 3.

It can be seen based on data in Table 1 and data in Table 2 that in a case where the values of the color coordinates are the same, compared with Control scheme 1, for Scheme 1, Scheme 2 and Scheme 5 in the light-emitting device 210 of the first color, both the current luminous efficiency and the effective service life of the light-emitting device may be improved. It can be understood that of different light-emitting layers in the same light-emitting device 200, the difference between ratios of the weights of the first compounds to the sums of the weights of the first compounds and the second compounds is limited to a small range, and/or the difference between ratios of the weights of the second compounds to the sums of the weights of the first compounds and the second compounds is limited to a small range, so that the current luminous efficiency of the light-emitting device 200 may be improved and the effective service life of the light-emitting device 200 may be prolonged.

It can be seen based on data in Table 1 and data in Table 2 that in a case where the values of the color coordinates are the same, compared with Control scheme 2, for Scheme 3, Scheme 4 and Scheme 6 in the light-emitting device 220 of the second color, both the current luminous efficiency and the effective service life of the light-emitting device may be improved. It can be understood that of different light-emitting layers in the same light-emitting device 200, the difference between ratios of the weights of the first compounds to the sums of the weights of the first compounds and the second compounds is limited to a small range, and/or the difference between ratios of the weights of the second compounds to the sums of the weights of the first compounds and the second compounds is limited to a small range, so that the current luminous efficiency of the light-emitting device 200 may be improved and the effective service life of the light-emitting device 200 may be prolonged.

To sum up, in the light-emitting device and the display panel provided by the embodiments of the present disclosure, by limiting a range of the difference between the ratios of the weights of the first compounds of different light-emitting layers in the same light-emitting device to the weights of the light-emitting layers to which the first compounds belong, and/or a range of the difference between the ratios of the weights of the second compounds of different light-emitting layers in the same light-emitting device to the weights of the light-emitting layers to which the second compounds belong, the exciton recombination areas of different light-emitting layers in the same light-emitting device may be consistent or close, and the performance difference between different light-emitting layers in the same light-emitting device may be reduced, thereby improving the luminous efficiency of the light-emitting device and prolonging the effective service life of the light-emitting device. In turn, the overall luminous efficiency of the display panel may be improved and the effective service life of the display panel may be prolonged.

FIG. 22 is a flow diagram of a method for manufacturing a display panel in accordance with some embodiments.

Referring to FIG. 22, some embodiments of the present disclosure provide a method for manufacturing the display panel. The method for manufacturing the display panel includes steps S510 to S540.

In step S510, first electrodes are formed.

As shown in FIG. 8, before step S510, the method may further include providing a base substrate SUB. A material of the base substrate SUB may be, for example, polyethylene terephthalate (PET), polyimide (PI), or cyclo olefin polymer (COP).

The base substrate SUB may include first sub-pixel areas P1, second sub-pixel areas P2 and third sub-pixel areas P3. The first sub-pixel areas P1, the second sub-pixel areas P2 and the third sub-pixel areas P3 have been described above in detail, and are not repeated here.

A pixel circuit layer is formed on the base substrate SUB. The pixel circuit layer includes a plurality of pixel circuits. The plurality of pixel circuits have been described above in detail, and are not repeated here.

After the plurality of pixel circuits are formed, an insulating layer INL covering the plurality of pixel circuits is formed.

In some examples, the first electrode AE may be an anode, and the anode may be formed on the insulating layer INL through a patterning process.

The anode may be made of a metal or combination of Ag, Mg, Al, Pt, Pd, Au, Ni, Nd, Ir or Cr, or may be made of a conductive metal oxide material such as ITO, IZO or IGZO. For example, the anode may also include a laminated composite structure of transparent conductive oxide/metal/transparent conductive oxide. The transparent conductive oxide material is, for example, ITO or IZO, and the metal material is, for example, Au, Ag, Ni or Pt. For example, the anode structure is: ITO/Ag/ITO.

The anode may include a first anode, a second anode and a third anode. The first anode is located in the first sub-pixel area P1, the second anode is located in the second sub-pixel area P2, and the third anode is located in the third sub-pixel area P3.

After step S510, the method may include: performing ultrasonic treat on the base substrate SUB on which the first electrode has been formed (e.g., a glass plate provided with ITO) in a cleaning agent (e.g., deionized water), so as to wash away organic substance and dust remained on surfaces of the first electrode and base substrate SUB; and then drying the first electrode and the base substrate SUB in a clean environment at a certain temperature (e.g., 100° C.).

In step S520, a pixel defining layer is formed on the first electrodes. The pixel defining layer is provided with a plurality of light-emitting openings therein, and the light-emitting openings expose the first electrodes.

The pixel defining layer PDL may be formed on the insulating layer and the anodes. For example, a pixel defining material layer covering the insulating layer and the anodes is formed by deposition, and part of the pixel defining material layer is removed by etching to obtain the pixel defining layer PDL. The pixel defining layer PDL includes a first light-emitting opening K1 located in the first sub-pixel area P1, a second light-emitting opening K2 located in the second sub-pixel area P2, and a third light-emitting opening K3 located in the third sub-pixel area P3.

The first light-emitting opening K1 exposes the first anode, the second light-emitting opening K2 exposes the second anode, and the third light-emitting opening K3 exposes the third anode.

In step S530, at least two light-emitting units covering the light-emitting opening are formed. The at least two light-emitting units include a first light-emitting unit and a second light-emitting unit sequentially stacked in the first direction. The first light-emitting unit includes a first light-emitting layer. The second light-emitting unit includes a second light-emitting layer. A light-emitting layer of each light-emitting unit includes a first compound, a second compound, and a third compound. An absolute value of a difference between a ratio of a weight of a first compound in the first light-emitting layer to a weight of the first light-emitting layer and a ratio of a weight of a first compound in the second light-emitting layer to a weight of the second light-emitting layer is in a range of 0% to 3%, inclusive; and/or an absolute value of a difference between a ratio of a weight of a second compound in the first light-emitting layer to the weight of the first light-emitting layer and a ratio of a weight of a second compound in the second light-emitting layer to the weight of the second light-emitting layer is in a range of 0% to 3%, inclusive.

As shown in FIGS. 2 and 9, in some examples, the first light-emitting unit 21 includes a first transport layer TL1, a first light-emitting layer, and a second transport layer TL2; and the second light-emitting unit 22 includes a third transport layer TL3, a second light-emitting layer, and a fourth transport layer TL4. S530 may include the following contents.

The first transport layer TL1 covering the first light-emitting opening K1, the second light-emitting opening K2 and the third light-emitting opening K3 is formed. The first transport layer TL1 may further cover the pixel defining layer PDL, and part of the first transport layer TL1 covering the pixel defining layer PDL and part of the first transport layer TL1 covering the light-emitting openings form a continuous film.

The first light-emitting layer covering the first light-emitting opening K1, the first light-emitting layer covering the second light-emitting opening K2, and the first light-emitting layer covering the third light-emitting opening K3 are formed on the first transport layer TL1. Two adjacent first light-emitting layers are independent of each other.

The second transport layer TL2 covering the plurality of first light-emitting layers is formed. The second transport layer TL2 may further cover the pixel defining layer PDL, and part of the second transport layer TL2 covering the pixel defining layer PDL and part of the second transport layer TL2 covering the light-emitting openings form a continuous film.

A charge generation layer 30 is formed. The charge generation layer 30 may cover the first light-emitting opening K1, the second light-emitting opening K2, the third light-emitting opening K3 and the pixel defining layer PDL. That is, the charge generation layer 30 covers the second transport layer TL2.

The third transport layer TL3 covering the charge generation layer 30 is formed. The third transport layer TL3 may cover the first light-emitting opening K1, the second light-emitting opening K2, the third light-emitting opening K3 and the pixel defining layer PDL, and part of the third transport layer TL3 covering the pixel defining layer PDL and part of the third transport layer TL3 covering the light-emitting openings form a continuous film.

The second light-emitting layer covering the first light-emitting opening K1, the second light-emitting layer covering the second light-emitting opening K2, and the second light-emitting layer covering the third light-emitting opening K3 are formed on the third transport layer TL3. Two adjacent second light-emitting layers are independent of each other.

The fourth transport layer TL4 covering the plurality of second light-emitting layers is formed. The fourth transport layer TL4 may further cover the pixel defining layer PDL, and part of the fourth transport layer TL4 covering the pixel defining layer PDL and part of the fourth transport layer TL4 covering the light-emitting openings form a continuous film.

In some examples, as shown in FIGS. 9 and 11, a light-emitting device includes two light-emitting layers, and the two light-emitting layers are a first light-emitting layer EML1 and a second light-emitting layer EML2. An absolute value of a difference between a ratio of the weight of the first compound in the first light-emitting layer EML1 to the weight of the first light-emitting layer EML1 and a ratio of the weight of the first compound in the second light-emitting layer EML2 to the weight of the second light-emitting layer EML2 is in a range of 0% to 3%, inclusive, such as 0%, 0.2%, 0.3%, 0.5%, 0.8%, 1%, 1.2%, 1.5%, 1.7%, 2%, 2.3%, 2.5%, 2.9% or 3%.

For example, in the first light-emitting layer EML1, a ratio of the weight of the first compound to a sum of weights of the first compound and the second compound is M1. In the second light-emitting layer EML2, a ratio of the weight of the first compound to a sum of weights of the first compound and the second compound is M2. An absolute value of the difference between M1 and M2 is in a range of 0% to 2%, inclusive, such as 0%, 0.1%, 0.3%, 0.6%, 0.8%, 1%, 1.2%, 1.5%, 1.7% or 2%.

In some examples, as shown in FIG. 10, a light-emitting device includes three light-emitting layers, and the three light-emitting layers are a first light-emitting layer EML1, a second light-emitting layer EML2, and a third light-emitting layer EML3.

An absolute value of a difference between a ratio of the weight of the first compound in the first light-emitting layer EML1 to the weight of the first light-emitting layer EML1 and a ratio of the weight of the first compound in the third light-emitting layer EML3 to the weight of the third light-emitting layer EML3 is in a range of 0% to 3%, inclusive, such as 0%, 0.2%, 0.3%, 0.5%, 0.8%, 1%, 1.2%, 1.5%, 1.7%, 2%, 2.3%, 2.5%, 2.9% or 3%.

For example, in a light-emitting device, in the first light-emitting layer EML1, a ratio of the weight of the first compound to a sum of weights of the first compound and the second compound is M1; and in the third light-emitting layer EML3, a ratio of the weight of the first compound to a sum of weights of the first compound and the second compound is M5. An absolute value of the difference between M1 and M5 is in a range of 0% to 2%, inclusive, such as 0%, 0.1%, 0.3%, 0.5%, 0.6%, 0.8%, 1%, 1.2%, 1.5%, 1.7% or 2%.

For example, as shown in FIG. 10, an absolute value of a difference between a ratio of the weight of the first compound in the second light-emitting layer EML2 to the weight of the second light-emitting layer EML2 and a ratio of the weight of the first compound in the third light-emitting layer EML3 to the weight of the third light-emitting layer EML3 is also in a range of 0% to 3%, inclusive.

For example, in a light-emitting device, in the second light-emitting layer EML2, a ratio of the weight of the first compound to a sum of the weights of the first compound and the second compound is M2; and in the third light-emitting layer EML3, a ratio of the weight of the first compound to a sum of the weights of the first compound and the second compound is M5. An absolute value of a difference between M2 and M5 is in a range of 0% to 2%, inclusive, such as 0%, 0.1%, 0.3%, 0.5%, 0.6%, 0.8%, 1%, 1.2%, 1.5%, 1.7% or 2%.

In some examples, an absolute value of a difference between a ratio of the weight of the second compound in the first light-emitting layer EML1 to the weight of the first light-emitting layer EML1 and a ratio of the weight of the second compound in the second light-emitting layer EML2 to the weight of the second light-emitting layer EML2 is in a range of 0% to 3%, inclusive, such as 0%, 0.2%, 0.3%, 0.5%, 0.8%, 1%, 1.2%, 1.5%, 1.7%, 2%, 2.3%, 2.5%, 2.9% or 3%.

For example, in the first light-emitting layer EML1, a ratio of the weight of the second compound to a sum of the weights of the first compound and the second compound is M3. In the second light-emitting layer EML2, a ratio of the weight of the second compound to a sum of the weights of the first compound and the second compound is M4. An absolute value of a difference between M3 and M4 is in a range of 0% to 2%, inclusive, such as 0%, 0.1%, 0.3%, 0.6%, 0.8%, 1%, 1.2%, 1.5%, 1.7% or 2%.

For example, an absolute value of a difference between a ratio of the weight of the second compound in the first light-emitting layer EML1 to the weight of the first light-emitting layer EML1 and a ratio of the weight of the second compound in the third light-emitting layer to the weight of the third light-emitting layer is in a range of 0% to 3%, inclusive, such as 0%, 0.2%, 0.3%, 0.5%, 0.8%, 1%, 1.2%, 1.5%, 1.7%, 2%, 2.3%, 2.5%, 2.9% or 3%.

For example, in the light-emitting device, in the first light-emitting layer EML1, a ratio of the weight of the second compound to a sum of the weights of the first compound and the second compound is M3; and in the third light-emitting layer EML3, a ratio of the weight of the second compound to a sum of the weights of the first compound and the second compound is M6. An absolute value of a difference between M3 and M6 is in a range of 0% to 2%, inclusive, such as 0%, 0.1%, 0.3%, 0.5%, 0.6%, 0.8%, 1%, 1.2%, 1.5%, 1.7% or 2%.

For example, an absolute value of a difference between a ratio of the weight of the second compound in the second light-emitting layer EML2 to the weight of the second light-emitting layer EML2 and a ratio of the weight of the second compound in the third light-emitting layer to the weight of the third light-emitting layer is also in a range of 0% to 3%, inclusive, such as 0%, 0.2%, 0.3%, 0.5%, 0.8%, 1%, 1.2%, 1.5%, 1.7%, 2%, 2.3%, 2.5%, 2.9% or 3%.

For example, in the light-emitting device, in the second light-emitting layer EML2, a ratio of the weight of the second compound to a sum of the weights of the first compound and the second compound is M4; and in the third light-emitting layer EML3, a ratio of the weight of the second compound to a sum of the weights of the first compound and the second compound is M6. An absolute value of a difference between M4 and M6 is in a range of 0% to 2%, inclusive, such as 0%, 0.1%, 0.3%, 0.5%, 0.6%, 0.8%, 1%, 1.2%, 1.5%, 1.7% or 2%.

It will be noted that the first compound, the second compound and the third compound are described in detail in the foregoing embodiments and are not repeated here.

In step S540, a second electrode is formed on a side of the at least two light-emitting units away from the first electrodes. The first light-emitting unit is located between the first electrode AE and the second electrode CE, and the second light-emitting unit is located between the first light-emitting unit and the second electrode CE. It can be understood that the second electrode is formed on a side of the second light-emitting unit away from the first electrode.

In some examples, as shown in FIG. 9, the second electrode CE is formed on a side of the second light-emitting unit 22 away from the first electrode AE, which may be understood as forming the second electrode CE covering the fourth transport layer TL4. The second electrode CE may cover the first light-emitting opening K1, the second light-emitting opening K2, the third light-emitting opening K3 and the pixel defining layer PDL, and part of the second electrode CE covering the pixel defining layer PDL and part of the second electrode CE covering the light-emitting openings form a continuous film.

In some examples, the second electrode may be a cathode, and the cathode may have semi-transmissive or transmissive properties. The cathode may include one or a compound or a mixture of Ag, Mg, Cu, Al, Pt, Pd, Au, Ni, Nd, Ir, Cr, Li, Ca, LiF/Ca, LiF/Al, Mo or Ti, such as a mixture of Ag and Mg.

In some examples, as shown in FIG. 9, the display panel is a top-emission display panel. After step S540, the method may further include forming a light extraction layer CPL on a side of the second electrode away from the base substrate SUB.

In the same light-emitting device in the display panel obtained by the method for manufacturing the display panel provided in the present embodiments, the ratios of the weights of the first compounds of different light-emitting layers to the weights of the light-emitting layers to which the first compounds belong have a small difference therebetween, and/or the ratios of the weights of the second compounds of different light-emitting layers to the weights of the light-emitting layers to which the second compounds belong have a small difference therebetween. As a result, exciton recombination areas of different light-emitting layers in the same light-emitting device are consistent or close, and the performance difference between different light-emitting layers in the same light-emitting device may be reduced, thereby improving the overall luminous efficiency and stability of the light-emitting device and the display panel.

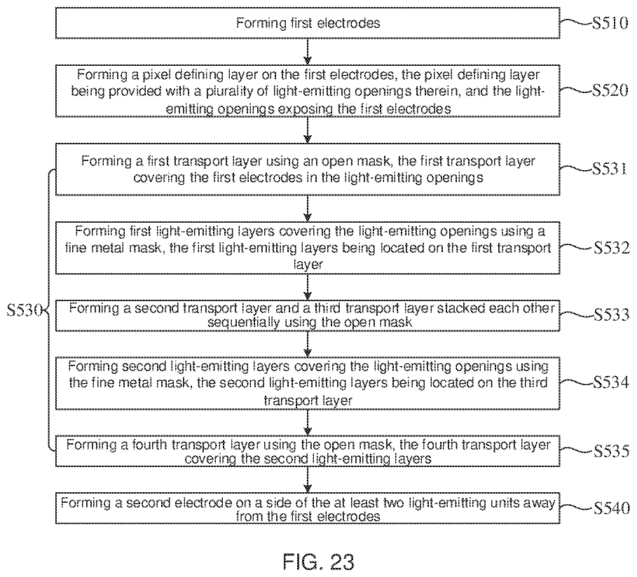

In some embodiments, as shown in FIGS. 9 and 23, S530 includes steps S531 to S535.

In step S531, the first transport layer TL1 is formed using an open mask, and the first transport layer TL1 covers the first electrodes AE in the light-emitting openings.

The open mask may be used for evaporation to form the first transport layer TL1 covering the pixel defining layer PDL and the first electrodes in all the light-emitting openings.

In some examples, the first transport layer TL1 may include a first hole injection layer HIL1, a first hole transport layer HTL1, and a first exciton blocking layer BL1. The first sub-pixel area P1, the second sub-pixel area P2 and the third sub-pixel area P3 have been described above in detail, and are not repeated here.

For example, S531 may include the following contents.

A hole injection material is evaporated on the pixel definition layer PDL and the first electrode AE in each light-emitting opening using the open mask to form the first hole injection layer HIL1. The hole injection material may use NPB:F4TCNQ or TAPC:MnO₃.

A hole transport material is evaporated on the first hole injection layer HIL1 using the open mask to form the first hole transport layer HTL1. The hole transport material may use carbazole organic materials with good hole mobilities.

A first exciton blocking material is evaporated on the first hole transport layer HTL1 using the open mask to form the first exciton blocking layer BL1. The first exciton blocking layer BL1 is configured to transport holes and block electrons in the subsequently formed first light-emitting layer EML1 from diffusing towards the first electrode AE. The first exciton blocking layer BL1 may be an electron blocking layer. The first exciton blocking material may be understood as an electron blocking material, and may include, for example, one or both of TPB or α-NPD.

In step S532, the first light-emitting layers covering the light-emitting openings are formed using a fine metal mask (FMM). The first light-emitting layers are located on the first transport layer.

In some examples, the first compound, the second compound and the third compound are evaporated simultaneously on the first exciton blocking layer BL1 in a plurality of light-emitting openings using the fine metal mask to form a plurality of first light-emitting layers.

For example, in each light-emitting layer, a ratio of the weight of the first compound to the weight of the second compound is in a range of 3:7 to 7:3, inclusive.

For example, in each light-emitting layer, a ratio of the weight of the third compound to a sum of the weights of the first compound and the second compound is in a range of 1% to 14%, inclusive.

For example, S532 may include the following contents.

The first compound, the second compound and the third compound are evaporated simultaneously on the first exciton blocking layer BL1 covering the first light-emitting opening K1 using the fine metal mask to form a first light-emitting layer of the light-emitting device 210 of the first color covering the first light-emitting opening K1. For example, in the first light-emitting layer of the light-emitting device 210 of the first color, a ratio of the weight of the first compound to the weight of the second compound is in a range of 5:5 to 7:3, inclusive. As another example, in the first light-emitting layer of the light-emitting device 210 of the first color, a ratio of the weight of the third compound to a sum of the weights of the first compound and the second compound is in a range of 6% to 14%, inclusive.

The first compound, the second compound and the third compound are evaporated simultaneously on the first exciton blocking layer BL1 covering the second light-emitting opening K2 using the fine metal mask to form a first light-emitting layer of the light-emitting device 220 of the second color covering the second light-emitting opening K2. For example, in the first light-emitting layer of the light-emitting device 220 of the second color, a ratio of the weight of the first compound to the weight of the second compound is in a range of 3:7 to 5:5, inclusive. As another example, in the first light-emitting layer of the light-emitting device 220 of the second color, a ratio of the weight of the third compound to a sum of the weights of the first compound and the second compound is in a range of 1% to 6%, inclusive.

In step S533, a second transport layer TL2 and a third transport layer TL3 stacked each other are sequentially formed using an open mask. The second transport layer TL2 covers the first light-emitting layer EML1.

In some examples, the second transport layer TL2 may include a first electron transport layer ETL1, a first electron injection layer EIL1, and a second exciton blocking layer BL2. Forming the second transport layer in step S533 may include the following contents.

A second exciton blocking material is evaporated using the open mask to form the second exciton blocking layer BL2 covering the first exciton blocking layer BL1 and the first light-emitting layer EML1. The second exciton blocking layer BL2 is configured to transport electrons and block holes in the first light-emitting layer EML1 from diffusing towards the second electrode CE. The second exciton blocking layer BL2 may be a hole blocking layer. The second exciton blocking material may be understood as a hole blocking material, and may be, for example, any of BCP (2,9-dimethyl-4,7-diphenyl-1,10-phenanthroline), Bphen (1,10-phenanthroline), or TPBI (1,3,5-tri(1-phenyl-1H-benzo[d]imidazol-2-yl)phenyl; 1,3,5-Tris(1-phenyl-1H-benzimidazol-2-yl)benzene).

An electron transport material is evaporated using the open mask to form the first electron transport layer ETL1 covering the second exciton blocking layer BL2. The electron transport material may use triazine-based organic materials with high electron mobilities.

An electron injection material is evaporated using the open mask to form the first electron injection layer EIL1 covering the first electron transport layer ETL1. The electron injection material may use at least one material selected from lithium fluoride or lithium 8-hydroxyquinolate.

In some examples, after the second transport layer TL2 is formed and before the third transport layer TL3 is formed, the method may further include: forming an N-type charge generation sub-layer 320 covering the first electron injection layer EIL1, and a P-type charge generation sub-layer 310 covering the N-type charge generation sub-layer 320. The N-type charge generation sub-layer 320 may cover the second transport layer TL2. The N-type charge generation sub-layer 320 is configured to provide electrons to the first electron injection layer EIL1. The P-type charge generation sub-layer 310 is configured to provide holes to the subsequently formed third transport layer TL3.

In some examples, the third transport layer TL3 may include a second hole injection layer HIL2, a second hole transport layer HTL2, and a third exciton blocking layer BL3. Forming the third transport layer in step S533 may include the following contents.

A hole injection material is evaporated using the open mask to form the second hole injection layer HIL2 located on a side of the first electron injection layer EIL1 away from the first electrode AE. The second hole injection layer HIL2 may cover the P-type charge generation sub-layer 310 to transport holes provided by the P-type charge generation sub-layer 310 to the second hole injection layer HIL2. The second hole injection layer HIL2 may have the same structural features as the first hole injection layer HIL1, and details are not repeated here.

A hole transport material is evaporated using the open mask to form the second hole transport layer HTL2 covering the second hole injection layer HIL2. The second hole transport layer HTL2 may have the same structural features as the first hole transport layer HTL1, and details are not repeated here.

A third exciton blocking material is evaporated using the open mask to form the third exciton blocking layer BL3 covering the second hole transport layer HTL2. The third exciton blocking layer BL3 is configured to transport holes and block electrons in the subsequently formed second light-emitting layer EML2 from diffusing towards the first electrode AE. The third exciton blocking layer BL3 may be called an electron blocking layer. The third exciton blocking material may be the same as the first exciton blocking material. The third exciton blocking layer BL3 may have the same structural features as the first exciton blocking layer BL1, and details are not repeated here.

In step S534, the second light-emitting layers EML2 covering the light-emitting openings are formed using the fine metal mask. The second light-emitting layers EML2 are located on the third transport layer TL3.

In some examples, the first compound, the second compound and the third compound are evaporated simultaneously using the fine metal mask to form the second light-emitting layers EML2 covering the plurality of light-emitting openings. The second light-emitting layer EML2 may cover the third exciton blocking layer BL3.

For other examples of forming the second light-emitting layer EML2 in step S534, reference may be made to the specific examples of forming the first light-emitting layer EML1 in step S532, and details are not repeated here.

In step S535, the fourth transport layer TL4 is formed using the open mask, and the fourth transport layer TL4 covers the second light-emitting layer EML2.

In some examples, the fourth transport layer TL4 includes a fourth exciton blocking layer BL4, a second electron transport layer ETL2, and a second electron injection layer EIL2.

S535 may include the following contents.

A fourth exciton blocking material is evaporated using the open mask to form the fourth exciton blocking layer BL4 covering the third exciton blocking layer BL3 and the second light-emitting layer EML2. The fourth exciton blocking layer BL4 is configured to transport electrons and block holes in the second light-emitting layer EML2 from diffusing towards the second electrode CE. The fourth exciton blocking layer BL4 may be called a hole blocking layer. The fourth exciton blocking material may be the same as the second exciton blocking material. The fourth exciton blocking layer BL4 may have the same structural features as the second exciton blocking layer BL2, and details are not repeated here.

An electron transport material is evaporated using the open mask to form the second electron transport layer ETL2 covering the fourth exciton blocking layer BL4. The second electron transport layer ETL2 may have the same structural features as the first electron transport layer ETL1, and details are not repeated here.

An electron injection material is evaporated using the open mask to form the second electron injection layer EIL2 covering the second electron transport layer ETL2. The second electron injection layer EIL2 may have the same structural features as the first electron injection layer EIL1, and details are not repeated here.

In the present embodiments, the open mask may be used to obtain common layer(s) each connecting and covering all the light-emitting openings, such as the first transport layer TL1, the second transport layer TL2, the third transport layer TL3, and the fourth transport layer TL4; and the fine metal mask may be used to form the first light-emitting layers EML1 and the second light-emitting layers EML2, thereby improving the position accuracy of the first light-emitting layers EML1 and the second light-emitting layers EML2, and improving the manufacturing efficiency of the display panel.

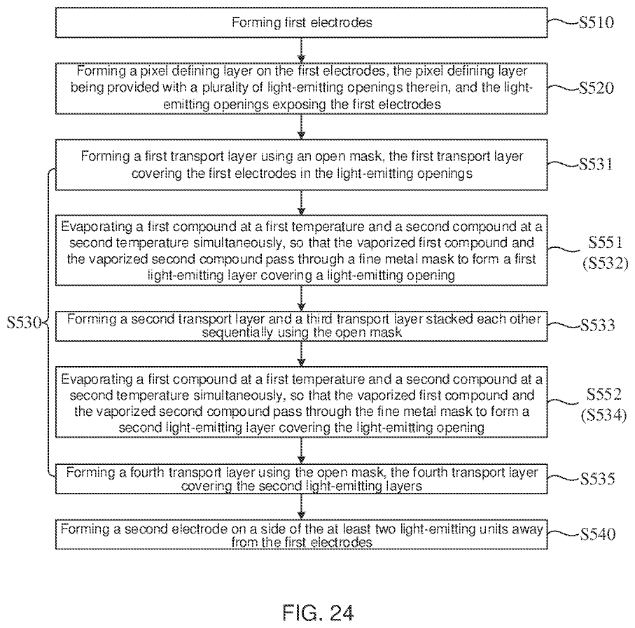

In some embodiments, as shown in FIG. 24, S532 may include a step S551.

In step S551, the first compound is evaporated at the first temperature, and the second compound is evaporated at the second temperature simultaneously, so that the vaporized first compound and the vaporized second compound pass through the fine metal mask to form the first light-emitting layer covering the light-emitting opening. An absolute value of a difference between the first temperature and the second temperature is in a range of 0° C. to 10° C., inclusive, such as 0° C., 2° C., 4° C., 5° C., 6° C., 8° C. or 10° C.

In some examples, the first compound is evaporated at the first temperature T1, and an evaporation rate of the first compound is 1 Å/s. Moreover, the second compound is evaporated at the second temperature T2, and an evaporation rate of the second compound is also 1 Å/s. The absolute value of the difference between the first temperature T1 and the second temperature T2 is in a range of 0° C. to 5° C., inclusive (i.e., 0° C.≤|T1−T2|≤5° C.), such as 0° C., 1° C., 2° C., 3° C., 4° C. or 5° C.

For example, S551 may include: weighing the first compound and the second compound, a ratio of the weight of the first compound to the weight of the second compound being in a range of 3:7 to 7:3; then, placing the weighed first compound into a first heating device (such as a crucible) for evaporation at the first temperature T1 (e.g., 154.3° C.), the evaporation rate of the first compound being 1 Å/s; meanwhile, placing the weighed second compound into a second heating device (such as a crucible) for evaporation at the second temperature T2 (e.g., 154.8° C.), the evaporation rate of the second compound being also 1 Å/s. The absolute value of the difference between the first temperature T1 and the second temperature T2 is 0.5° C. In the present examples, the first compound and the second compound are respectively placed into two heating devices for evaporation. In some other examples, the first compound and the second compound may also be placed in the same heating device for evaporation. In this case, the first temperature T1 and the second temperature T2 are equal.

The evaporation temperature of the third compound may be the same as or different from the evaporation temperature of the first compound and the evaporation temperature of the second compound, which is not limited here.

The first compound, the second compound and the third compound have been described above in detail, and are not repeated here.

S534 may include a step S552. S552 may include: simultaneously evaporating the first compound at the first temperature and evaporating a second compound at the second temperature, so that the vaporized first compound and the vaporized second compound pass through the fine metal mask to form the second light-emitting layer covering the light-emitting opening.

For specific examples of forming the second light-emitting layer in step S552, reference may be made to the specific examples of forming the first light-emitting layer in step S551, and details are not repeated here.

In each light-emitting layer or all light-emitting layers of a light-emitting device, a great difference between the evaporation temperature of the first compound and the evaporation temperature of the second compound will lead to a great difference between ratios in weight of the first compounds, the second compounds and the third compounds of different light-emitting layers in the same light-emitting device.

In the present embodiments, a small difference between the evaporation temperature of the first compound and the evaporation temperature of the second compound may ensure that the evaporation rate of the first compound and the evaporation rate of the second compound are approximately the same, and further ensure that the ratio of the weight of the first compound to the weight of the second compound in each light-emitting layer of the same light-emitting device remains unchanged during evaporation and after evaporation, that is, of different light-emitting layers in the same light-emitting device obtained by evaporation, ratios of the weights of the first compounds to the weights of the second compounds have a small difference, so that the exciton recombination areas of different light-emitting layers in the same light-emitting device may remain consistent or close, and the performance difference between different light-emitting layers in the same light-emitting device may be reduced, thereby improving the overall luminous efficiency and stability of the light-emitting device and the display panel.

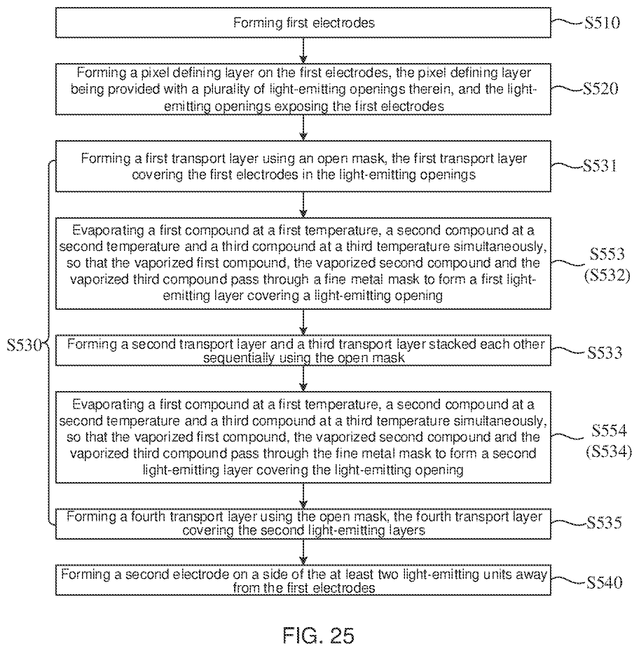

In some embodiments, as shown in FIG. 25, S532 may include a step S553.

In step S553, the first compound is evaporated at the first temperature T1, the second compound is evaporated at the second temperature T2, and the third compound is evaporated at the third temperature T3 simultaneously, so that the vaporized first compound, the vaporized second compound and the vaporized third compound pass through the fine metal mask to form the first light-emitting layer covering the light-emitting opening. An absolute value of a difference between the third temperature and the first temperature is in a range of 0° C. to 100° C., inclusive (i.e., 0° C.≤|T3−T1|≤100° C.), such as 0° C., 5° C., 15° C., 25° C., 35° C., 45° C., 55° C., 65° C., 75° C., 85° C., 90° C., 95° C. or 100° C.

In some embodiments, in the above step S553, an absolute value of a difference between the third temperature T3 and the second temperature T2 is in a range of 0° C. to 100° C., inclusive (i.e., 0° C.≤|T3−T2|≤100° C.), such as 0° C., 5° C., 15° C., 25° C., 35° C., 45° C., 55° C., 65° C., 75° C., 85° C., 90° C., 95° C. or 100° C.

In some examples, S553 may include: simultaneously evaporating the first compound at the first temperature T1, evaporating the second compound at the second temperature T2, and evaporating the third compound at the third temperature T3. An absolute value of a difference between the third temperature T3 and an average value of the first temperature T1 and the second temperature T2 is in a range of 0° C. to 90° C., inclusive (i.e., 0° C.≤|T3−(T1+T2)/2|≤90° C.), such as 0° C., 10° C., 20° C., 30° C., 40° C., 50° C., 60° C., 70° C., 80° C. or 90° C.

For example, the first compound is placed into a first heating device (e.g., a crucible) for evaporation at the first temperature T1 (e.g., 154.3° C.), and the evaporation rate of the first compound is 1 Å/s. Simultaneously, the second compound is placed into a second heating device (e.g., a crucible) for evaporation at the second temperature T2 (e.g., 154.8° C.), and the evaporation rate of the second compound is also 1 Å/s. Simultaneously, the third compound is placed into a third heating device (e.g., a crucible) for evaporation at the third temperature T3 (e.g., 221.5° C.), and the evaporation rate of the third compound is 0.1 Å/s. The absolute value of the difference between the third temperature T3 and the average value of the first temperature T1 and the second temperature T2 may be 66.95° C. In the present examples, the first compound, the second compound and the third compound are respectively placed in three heating devices for evaporation. In some other examples, the first compound and the second compound may also be placed in the same heating device for evaporation (i.e., the first temperature T1 and the second temperature T2 being equal), and simultaneously the third compound may be placed in another heating device for evaporation.

S534 may include a step S554. S554 may include: simultaneously evaporating the first compound at the first temperature, evaporating the second compound at the second temperature, and evaporating the third compound at the third temperature, so that the vaporized first compound, the vaporized second compound and the vaporized third compound pass through the fine metal mask to form the second light-emitting layer covering the light-emitting opening.

For specific examples of forming the second light-emitting layer in step S554, reference may be made to the specific examples of forming the first light-emitting layer in step S553, and details are not repeated here.

During evaporating the first compound, the second compound and the third compound to form the light-emitting layer, due to different material properties of the first compound, the second compound and the third compound, the evaporation rates and evaporation temperatures are different. The third compound has a relatively high evaporation temperature.

In the present embodiments, by limiting the deviation range between the evaporation temperature of the first compound, the evaporation temperature of the second compound, and the evaporation temperature of the third compound, it may avoid overheating damage to the first compound and the second compound caused by a relatively high evaporation temperature during evaporation, thereby improving the stability of the light-emitting device and prolonging the effective service life of the light-emitting device.

In the aforementioned Table 1, the “first temperature T1” represents the evaporation temperature of the first compound; the “second temperature T2” represents the evaporation temperature of the second compound; and the “third temperature T3” represents the evaporation temperature of the third compound.

It can be seen referring to the parameters in Table 1 that compared with Control scheme 1, in Scheme 1, Scheme 2 and Scheme 5, the absolute value of the difference between the evaporation temperature T1 of the first compound and the evaporation temperature T2 of the second compound (i.e., |T1−T2|) is in a small range; and the absolute value of the difference between the evaporation temperature T3 of the third compound and the average value of the evaporation temperature T1 of the first compound and the evaporation temperature T2 of the second compound (i.e. |T3−(T1+T2)/2|) is also in a small range. As a result, the evaporation rate of the first compound and the evaporation rate of the second compound in each light-emitting layer are approximately the same, and the difference between ratios of the weights of the first compounds to the weights of the second compounds of different light-emitting layers in the light-emitting device of the first color is in a small range. Furthermore, in the light-emitting device of the first color, the absolute value of the difference between ratios of the weights of the first compounds of different light-emitting layers to the sum of the weights of the first compounds and the weights of the second compounds, and/or the absolute value of the difference between ratios of the weights of the second compounds of different light-emitting layers to the sum of the weights of the first compounds and the weights of the second compounds may also be in a small range. Moreover, the difference between ratios of the weights of the third compounds of different light-emitting layers in the light-emitting device of the first color to the sum of the weights of the first compounds and the weights of the second compounds is in a small range. It can be understood that in the same light-emitting device, the absolute value of the difference between ratios of the weights of the first compounds of different light-emitting layers to the weights of the light-emitting layers to which the first compounds belong, and/or the absolute value of the difference between ratios of the weights of the second compounds of different light-emitting layers to the weights of the light-emitting layers to which the second compounds belong are each in a small range.

As described in detail above, the light-emitting device and the display panel provided by the embodiments of the present disclosure have the beneficial effects of high overall luminous efficiency and long effective service life. Therefore, on a basis of obtaining a light-emitting device and a display panel using the method for manufacturing the display panel provided by the embodiments of the present disclosure, the beneficial effects of the above light-emitting device and display panel may also be achieved.

To sum up, some embodiments of the present disclosure provide a light-emitting device, a display panel and a method for manufacturing the same, By limiting a range of the difference between the ratios of the weights of the first compounds of different light-emitting layers in the light-emitting device to the weights of the light-emitting layers to which the first compounds belong, and/or a range of the difference between the ratios of the weights of the second compounds of different light-emitting layers in the light-emitting device to the weights of the light-emitting layers to which the second compounds belong, the exciton recombination areas of different light-emitting layers may be consistent or close, and the performance difference between different light-emitting layers in the same light-emitting device may be reduced, thereby improving the overall luminous efficiency and stability of the light-emitting device and the display panel.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising:
a first electrode, at least two light-emitting units and a second electrode sequentially stacked in a first direction, wherein
the at least two light-emitting units include a first light-emitting unit and a second light-emitting unit; the first light-emitting unit is located between the first electrode and the second electrode, and the first light-emitting unit includes a first light-emitting layer; the second light-emitting unit is located between the first light-emitting unit and the second electrode, and the second light-emitting unit includes a second light-emitting layer;
a light-emitting layer of each light-emitting unit includes a first compound, a second compound and a third compound; and the first light-emitting layer and the second light-emitting layer satisfy at least one of;
an absolute value of a difference between a ratio of a weight of a first compound in the first light-emitting layer to a weight of the first light-emitting layer and a ratio of a weight of a first compound in the second light-emitting layer to a weight of the second light-emitting layer is in a range of 0% to 3%, inclusive; and
an absolute value of a difference between a ratio of a weight of a second compound in the first light-emitting layer to the weight of the first light-emitting layer and a ratio of a weight of a second compound in the second light-emitting layer to the weight of the second light-emitting layer is in a range of 0% to 3%, inclusive.

2. The light-emitting device according to claim 1, wherein in the first light-emitting layer, a ratio of the weight of the first compound to a sum of weights of the first compound and the second compound is M1;
in the second light-emitting layer, a ratio of the weight of the first compound to a sum of weights of the first compound and the second compound is M2; and
an absolute value of a difference between M1 and M2 is in a range of 0% to 2%, inclusive.

3. The light-emitting device according to claim 1, wherein in the first light-emitting layer, a ratio of the weight of the second compound to a sum of weights of the first compound and the second compound is M3;
in the second light-emitting layer, a ratio of the weight of the second compound to a sum of weights of the first compound and the second compound is M4; and
an absolute value of a difference between M3 and M4 is in a range of 0% to 2%, inclusive.

4. The light-emitting device according to claim 1, wherein in each light-emitting layer, a ratio of a weight of the first compound to a weight of the second compound is in a range of 3:7 to 7:3, inclusive.

5. The light-emitting device according to claim 1, wherein in each light-emitting layer, a ratio of a weight of the third compound to a sum of weights of the first compound and the second compound is in a range of 1% to 14%, inclusive.

6. The light-emitting device according to claim 1, further comprising:
a charge generation layer disposed between two adjacent light-emitting units and coupled to the adjacent light-emitting units.

7. The light-emitting device according to claim 1, wherein an absolute value of a difference between a wavelength of light emitted by the first light-emitting layer and a wavelength of light emitted by the second light-emitting layer is less than or equal to 20 nm.

8. The light-emitting device according to claim 1, wherein the at least two light-emitting units further include a third light-emitting unit; the third light-emitting unit is located between the second light-emitting unit and the second electrode and includes a third light-emitting layer;
an absolute value of a difference between a ratio of the weight of the first compound in the first light-emitting layer to the weight of the first light-emitting layer and a ratio of a weight of a first compound in the third light-emitting layer to a weight of the third light-emitting layer is in a range of 0% to 3%, inclusive; and/or
an absolute value of a difference between a ratio of the weight of the second compound in the first light-emitting layer to the weight of the first light-emitting layer and a ratio of a weight of a second compound in the third light-emitting layer to the weight of the third light-emitting layer is in a range of 0% to 3%, inclusive.

9. The light-emitting device according to claim 8, wherein in the first light-emitting layer, a ratio of the weight of the first compound to a sum of weights of the first compound and the second compound is M1;
in the third light-emitting layer, a ratio of the weight of the first compound to a sum of weights of the first compound and the second compound is M5; and
an absolute value of a difference between M1 and M5 is in a range of 0% to 2%, inclusive.

10. The light-emitting device according to claim 8, wherein in the first light-emitting layer, a ratio of the weight of the second compound to a sum of weights of the first compound and the second compound is M3;
in the third light-emitting layer, a ratio of the weight of the second compound to a sum of weights of the first compound and the second compound is M6; and
an absolute value of a difference between M3 and M6 is in a range of 0% to 2%, inclusive.

11. The light-emitting device according to claim 8, wherein an absolute value of a difference between the ratio of the weight of the first compound in the second light-emitting layer to the weight of the second light-emitting layer and the ratio of the weight of the first compound in the third light-emitting layer to the weight of the third light-emitting layer is in a range of 0% to 3%, inclusive; and/or
an absolute value of a difference between the ratio of the weight of the second compound in the second light-emitting layer to the weight of the second light-emitting layer and the ratio of the weight of the second compound in the third light-emitting layer to the weight of the third light-emitting layer is in a range of 0% to 3%, inclusive.

12. A display panel, comprising:
a pixel defining layer provided with a plurality of light-emitting openings therein; and
a plurality of light-emitting devices covering plurality of light-emitting openings, respectively; each light-emitting device is the light-emitting device according to claim 1.

13. The display panel according to claim 12, wherein the plurality of light-emitting devices include a light-emitting device of a first color and a light-emitting device of a second color;
a wavelength of light emitted by the light-emitting device of the first color is less than a wavelength of light emitted by the light-emitting device of the second color; and
a ratio of a weight of a first compound to a weight of a second compound in a light-emitting layer of the light-emitting device of the first color is greater than or equal to a ratio of a weight of a first compound to a weight of a second compound in a light-emitting layer of the light-emitting device of the second color.

14. The display panel according to claim 13, wherein
the ratio of the weight of the first compound to the weight of the second compound in the light-emitting layer of the light-emitting device of the first color is in a range of 5:5 to 7:3, inclusive; and
the ratio of the weight of the first compound to the weight of the second compound in the light-emitting layer of the light-emitting device of the second color is in a range of 3:7 to 5:5, inclusive.

15. The display panel according to claim 12, wherein the plurality of light-emitting devices include a light-emitting device of a first color and a light-emitting device of a second color;
a wavelength of light emitted by the light-emitting device of the first color is less than a wavelength of light emitted by the light-emitting device of the second color; and
a ratio of a weight of a third compound to a sum of weights of a first compound and a second compound in a light-emitting layer of the light-emitting device of the first color is greater than or equal to a ratio of a weight of a third compound to a sum of weights of a first compound and a second compound in a light-emitting layer of the light-emitting device of the second color.

16. The display panel according to claim 15, wherein
the ratio of the weight of the third compound to the sum of the weights of the first compound and the second compound in the light-emitting layer of the light-emitting device of the first color is in a range of 6% to 14%, inclusive; and
the ratio of the weight of the third compound to the sum of the weights of the first compound and the second compound in the light-emitting layer of the light-emitting device of the second color is in a range of 1% to 6%, inclusive.

17. A method for manufacturing a display panel, comprising:
forming a first electrode;
forming a pixel defining layer on the first electrode, the pixel defining layer being provided with a plurality of light-emitting openings therein, and a light-emitting opening exposing the first electrode;
forming at least two light-emitting units covering the light-emitting opening, wherein the at least two light-emitting units include a first light-emitting unit and a second light-emitting unit sequentially stacked in a first direction; the first light-emitting unit includes a first light-emitting layer; the second light-emitting unit includes a second light-emitting layer; a light-emitting layer of each light-emitting unit includes a first compound, a second compound and a third compound; and the first light-emitting layer and the second light-emitting layer satisfy at least one of: an absolute value of a difference between a ratio of a weight of a first compound in the first light-emitting layer to a weight of the first light-emitting layer and a ratio of a weight of a first compound in the second light-emitting layer to a weight of the second light-emitting layer is in a range of 0% to 3%, inclusive; and an absolute value of a difference between a ratio of a weight of a second compound in the first light-emitting layer to the weight of the first light-emitting layer and a ratio of a weight of a second compound in the second light-emitting layer to the weight of the second light-emitting layer is in a range of 0% to 3%, inclusive; and
forming a second electrode on a side of the at least two light-emitting units away from the first electrode; the first light-emitting unit being located between the first electrode and the second electrode, and the second light-emitting unit being located between the first light-emitting unit and the second electrode.

18. The method for manufacturing the display panel according to claim 17, wherein forming the at least two light-emitting units covering the light-emitting opening includes:
using an open mask to form a first transport layer, the first transport layer covering the first electrode in the light-emitting opening;
using a fine metal mask to form the first light-emitting layer covering the light-emitting opening, the first light-emitting layer being located on the first transport layer;
using an open mask to sequentially form a second transport layer and a third transport layer that are stacked each other, the second transport layer covering the first light-emitting layer;
using a fine metal mask to form the second light-emitting layer covering the light-emitting opening, the second light-emitting layer being located on the third transport layer; and
using an open mask to form a fourth transport layer, the fourth transport layer covering the second light-emitting layer.

19. The method for manufacturing the display panel according to claim 18, wherein using the fine metal mask to form the first light-emitting layer covering the light-emitting opening includes:
evaporating the first compound at a first temperature and the second compound at a second temperature simultaneously to allow the vaporized first compound and the vaporized second compound to pass through the fine metal mask to form the first light-emitting layer covering the light-emitting opening, wherein an absolute value of a difference between the first temperature and the second temperature is in a range of 0° C. to 10° C., inclusive.

20. The method for manufacturing the display panel according to claim 18, wherein using the fine metal mask to form the first light-emitting layer covering the light-emitting opening includes:
evaporating the first compound at a first temperature, the second compound at a second temperature and the third compound at a third temperature simultaneously to allow the vaporized first compound, the vaporized second compound and the vaporized third compound to pass through the fine metal mask to form the first light-emitting layer covering the light-emitting opening, wherein an absolute value of a difference between the third temperature and the first temperature is in a range of 0° C. to 100° C., inclusive; and/or an absolute value of a difference between the third temperature and the second temperature is in a range of 0° C. to 100° C., inclusive.
